(19) United States
(12) Patent Application Publication
(10) Pub. No.: US 2021/0385394 A1
(43) Pub. Date: Dec. 9, 2021

(54) SOLID-STATE IMAGING APPARATUS AND ELECTRONIC

(71) Applicant: SONY SEMICONDUCTOR SOLUTIONS CORPORATION, KANAGAWA (JP)

(72) Inventors: TETSUYUKI MIYAWAKI, KANAGAWA (JP); RYOJI SUZUKI, KANAGAWA (JP)

(21) Appl. No.: 17/284,301

(22) PCT Filed: Oct. 4, 2019
(86) PCT No.: PCT/JP2019/039240

§ 371 Date: Apr. 9, 2021

(30) Foreign Application Priority Data
Oct. 19, 2018 (JP) 2018-197711

(51) Int. Cl. H04N 5/345; H04N 5/378; H04N 5/3745; H04N 5/369; H04N 5/347; H04N 5/357; H01L 27/146

(52) U.S. Cl. CPC H04N 5/345; H04N 5/378; H04N 5/37455; H04N 5/36963; H04N 5/347; H04N 5/3572; H01L 27/14645; H01L 27/14607; H01L 27/14621; H01L 27/14623; H01L 27/14627; H01L 27/1463; H01L 27/14605

(57) ABSTRACT

The present technology relates to solid-state imaging apparatuses and electronic equipment, each of which is capable of contributing to an increased sense of resolution at an outer peripheral portion of an image photographed by using a wide-angle lens. The solid-state imaging apparatus includes a pixel array section in which a plurality of pixels is arranged such that a pixel pitch becomes smaller at a greater distance away from a central portion toward an outer peripheral portion. The present technology is applicable to, for example, solid-state imaging apparatuses and the like suited for photographing by using a wide-angle lens such as a fisheye lens used in a 360-degree panoramic camera.

### TECHNICAL FIELD

The present technology relates to solid-state imaging apparatuses and electronic equipment, and more particularly to solid-state imaging apparatuses and electronic equipment each of which is suitable for photographing by using a wide-angle lens such as a fisheye lens.

### BACKGROUND ART

An image taken by photographing using a wide-angle lens such as a fisheye lens for use in a 360-degree panoramic camera provides poorer quality in sense of resolution of the outer peripheral portion of an image than that of the central portion of the image. This is because the image of a subject formed as the image on a light receiving element is dense at the outer peripheral portion. As a result, the quality of an image is different between at the central portion and at the outer peripheral portion of the image.

As an imaging element in which resolution in its light receiving region is made different between the central portion and the outer peripheral portion of the region, an imaging element described in PTL 1 has been known, for example. The imaging element has a structure in which its pixel pitch becomes larger at a greater distance away from the central portion toward the outer periphery of the light receiving region. This has a further adverse effect on such a reduced sense of resolution at the outer peripheral portions which is concerned when using a wide-angle lens.

### CITATION LIST

### Patent Literature

### [PTL 1]

JP 2006-324354A

### SUMMARY

### Technical Problem

The present technology is made in view of such a situation and aimed at contributing to the improvement in sense of resolution at an outer peripheral portion of an image taken using a wide-angle lens.

### Solution to Problem

A solid-state imaging apparatus according to a first aspect of the present technology includes a pixel array section including a plurality of pixels arranged with a pixel pitch, the pixel array section having a central portion and an outer peripheral portion, the pixel pitch being smaller at a greater distance away from the central portion toward the outer peripheral portion.

A solid-state imaging apparatus according to a second aspect of the present technology includes a pixel array section including a plurality of pixels, and a controller configured to determine an effective area for the plurality of pixels in the pixel array section such that drive of pixels is performed and to perform control such that drive of pixels, among the plurality of pixels, located outside the effective area is halted.

Electronic equipment according to a third aspect of the present technology includes a solid-state imaging apparatus that includes a pixel array section including a plurality of pixels arranged with a pixel pitch, the pixel array section having a central portion and an outer peripheral portion, the pixel pitch being smaller at a greater distance away from the central portion toward the outer peripheral portion.

According to the first and third aspects of the present technology, the pixel array section is disposed in which a plurality of pixels is arranged with a pixel pitch such that the pixel pitch is smaller at a greater distance away from the central portion toward the outer peripheral portion.

According to the second aspect of the present technology, an effective area is determined for the plurality of pixels in the pixel array section such that drive of pixels is performed. Pixels located outside the effective area are subjected to control such that drive of the pixels is halted.

The solid-state imaging apparatuses and the electronic equipment may be independent apparatuses or may be modules incorporated in other apparatuses.

### BRIEF DESCRIPTION OF DRAWINGS

FIG. 1 is a diagram depicting an example of a schematic configuration of a solid-state imaging apparatus to which the present technology is applied.

FIG. 2 is a diagram depicting a feature of a fisheye lens.

FIG. 3 is a plan view depicting an example of a first configuration of a pixel array section.

FIG. 4 is a plan view depicting an example of a modification of a pixel shape.

FIG. 5 is a diagram depicting an example of a first arrangement of pixel drive lines and output signal lines in a concentric arrangement of pixels.

FIG. 6 is a detailed diagram depicting an example of a configuration of a pixel and an AD conversion section.

FIG. 7 is a diagram depicting an example of a second arrangement of pixel drive lines and output signal lines in the concentric arrangement of the pixels.

FIG. 8 is a diagram depicting an example of an arrangement of a peripheral circuit section corresponding to the second arrangement.

FIG. 9 is a cross-sectional diagram depicting cross-sectional structures of the pixels.

FIG. 10 is a plan view depicting an example of an arrangement of color filters.

FIG. 11 is a diagram depicting an example of a configuration in which an ADC is disposed on a per unit of pixel basis.

FIG. 12 is a conceptual diagram depicting a case of a solid-state imaging apparatus being formed in a laminated structure of three semiconductor substrates.

FIG. 13 is a schematic cross-sectional diagram depicting a case of the solid-state imaging apparatus including the three semiconductor substrates.

FIG. 14 is a plan view depicting an example of a second configuration of a pixel array section.

FIG. 15 is a diagram illustrating pixel drive in a non-projection region.

FIG. 16 is a plan view depicting an example of an arrangement of sub-pixels in a matrix.

FIG. 17 is a diagram depicting a pixel circuit in a case where the sub-pixels are arranged in a matrix.

FIG. 18 is a diagram depicting an example of an arrangement of color filters in each sub-pixel.

FIG. 19 is a diagram depicting drive timing charts for sub-pixels.

FIG. 20 is a diagram illustrating real-time control of a drive area.

FIG. 21 is a block diagram of a system controller relating to real-time control of a drive area.

FIG. 22 is a flowchart illustrating a real-time control processing of a drive area.

FIG. 23 is a block diagram depicting an example of a configuration of the imaging apparatus as electronic equipment to which the present technology is applied.

FIG. 24 is a diagram depicting examples of uses of image sensors.

FIG. 25 is a block diagram depicting an example of schematic configuration of a vehicle control system.

FIG. 26 is a diagram of assistance in explaining an example of installation positions of an outside-vehicle information detecting section and an imaging section.

### DESCRIPTION OF EMBODIMENTS

Hereinafter, modes for carrying out the present technology (hereinafter, referred to as “embodiments”) will be described. Note that the description will be made in the following order.

1. Exemplary Overall Configuration of Solid-State Imaging Apparatus

2. First Exemplary Configuration of Pixel Array Section

3. Second Exemplary Configuration of Pixel Array Section

4. Real-Time Control of Drive Area

5. Exemplary Application to Electronic Equipment

6. Exemplary Application to Mobile Body

### 1. Exemplary Overall Configuration of Solid-State Imaging Apparatus

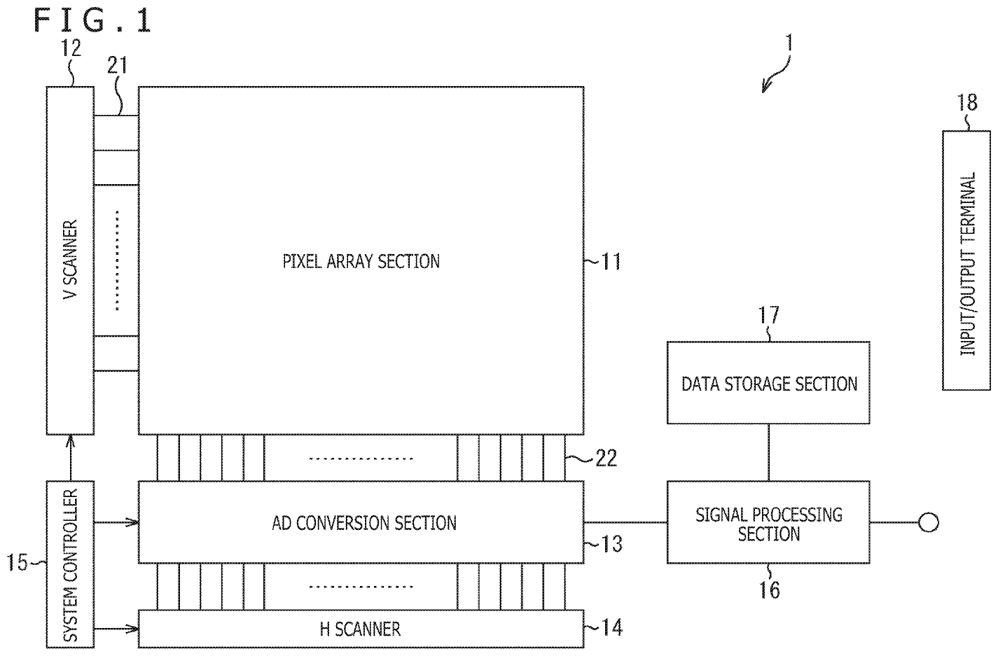

FIG. 1 is a block diagram depicting an example of a schematic configuration of a solid-state imaging apparatus to which the present technology is applied.

A solid-state imaging apparatus 1 depicted in FIG. 1 includes a pixel array section 11 and a peripheral circuit section disposed in the periphery thereof. The peripheral circuit section includes a V scanner (vertical drive section) 12, an AD conversion section 13, an H scanner (horizontal drive section) 14, a system controller 15, and the like. The solid-state imaging apparatus 1 is further provided with a signal processing section 16, a data storage section 17, input/output terminals 18, and the like.

The pixel array section 11 has a configuration in which a plurality of pixels is arranged each of which includes a photoelectric conversion section that generates and accumulates photocharge according to an amount of received light. Each of the pixels formed in the pixel array section 11 is connected to the V scanner 12 with a pixel drive line 21, and each pixel of the pixel array section 11 is driven by the V scanner 12 on a per unit-of-pixel or unit-of-plural pixels basis. The V scanner 12 includes a shift register, an address decoder, or the like and drives each pixel of the pixel array section 11 on an all-pixels-at-once or per unit of pixel line basis. The pixel drive line 21 transmits a drive signal for driving when a signal is to be read from the pixel.

Further, each pixel formed in the pixel array section 11 is connected to the AD conversion section 13 via an output signal line 22, and the output signal line 22 outputs, to the AD conversion section 13, a pixel signal that is generated by a corresponding pixel of the pixel array section 11. The AD conversion section 13 performs an AD (Analog to Digital) conversion processing and the like for an analog pixel signal that is fed from each pixel of the pixel array section 11.

The H scanner 14 includes a shift register, an address decoder, or the like, selects a pixel signal from among the pixel signals which have been subjected to AD conversion and stored by the AD conversion section 13 in a predetermined order, and causes the thus-selected signal to be output to the signal processing section 16.

The system controller 15 includes a timing generator, which generates various timing signals, and the like and performs drive control of the V scanner 12, the AD conversion section 13, the H scanner 14, and the like, on the basis of the various timing signals generated by the timing generator.

The signal processing section 16 has at least an arithmetic processing function and performs various kinds of signal processing such as arithmetic processing, on the basis of the pixel signal fed from the AD conversion section 13. The data storage section 17 temporarily stores data necessary for the signal processing performed by the signal processing section 16. The input/output terminals 18 include output terminals for outputting pixel signals to the outside and input terminals for receiving predetermined input signals from the outside.

The solid-state imaging apparatus 1 configured as described above is a CMOS image sensor that performs the AD conversion on the pixel signal generated by each pixel of the pixel array section 11 and that outputs the resulting signal.

The solid-state imaging apparatus 1 is such that the arrangement of pixels in the pixel array section 11 is one suitable for photographing by using a fisheye lens (wide-angle lens) for use in a 360-degree panoramic camera.

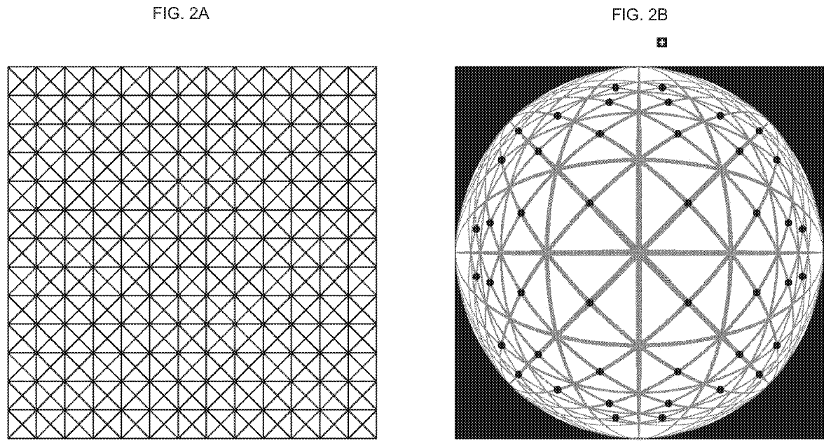

FIG. 2 is a diagram depicting a feature of a fisheye lens.

In the case where a subject having equally arranged square grids as depicted in sub-diagram A of FIG. 2 is photographed by using a fisheye lens, the obtained image is one as depicted in sub-diagram B of FIG. 2. That is, the image projected by using a fisheye lens is such a circular image that the pitch at the central portion of the circle is large and that the pitch becomes smaller at a greater distance away from the center toward the outer peripheral portion (circumferential portion). The black-filled areas at the four corners outside the circle are non-projection regions on which no image of the subject is projected. As described above, the image projected by using a fisheye lens is such that the projected pitch is different between at the central portion and the outer peripheral portion of a light receiving region. Therefore, the arrangement of pixels in the pixel array section 11 is preferably such that, assuming that the centers of pixels are located at positions indicated by black circles in sub-diagram B of FIG. 2, the pixel pitch becomes smaller, i.e., narrower pitch, at a greater distance away from the central portion toward the peripheral portion.

### 2. First Exemplary Configuration of Pixel Array Section

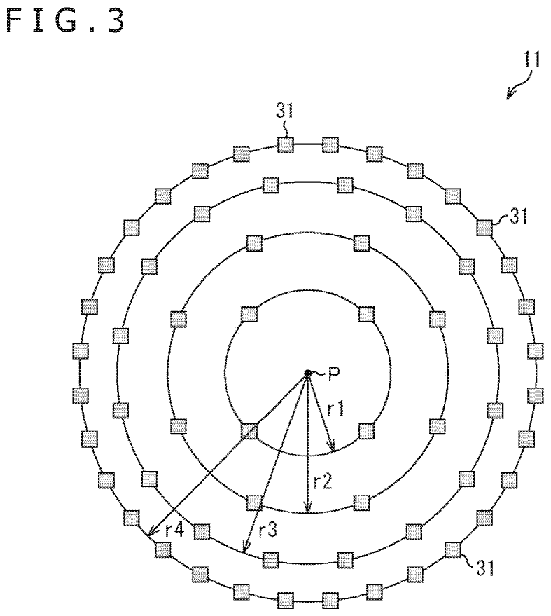

FIG. 3 is a plan view depicting an example of a first configuration of the pixel array section 11.

The first configuration of the pixel array section 11 has a concentric arrangement in which the pixels 31 are arranged on the circumferences of concentric circles. That is, in the first exemplary configuration, the pixels 31 are arranged on the polar coordinate system represented by a radius r and an angle θ, with the plane center position P of the pixel array section 11 being the center of the circles. The pixels 31 are arranged such that there exist four pixels on the circumference of a radius r1, eight pixels on the circumference of a radius r2, 16 pixels on the circumference of a radius r3, and 32 pixels on the circumference of a radius r4 in this order from the side nearer to the plane center position P of the pixel array section 11. The difference in the radius r between two adjacent circumferences on which the pixels 31 are arranged becomes smaller as the two adjacent circumferences approach the outer periphery. In the case depicted in FIG. 3, (r2−r1)>(r3−r2)>(r4−r3) is satisfied. That is, since the pixel pitch in the pixel array section 11 becomes smaller at a greater distance away from the central portion toward the outer peripheral portion (circumferential portion), the pitch configuration is similar to that of the image projected by a fisheye lens. This configuration makes it possible to improve sense of resolution at outer peripheral portions of the image photographed by using a fisheye lens.

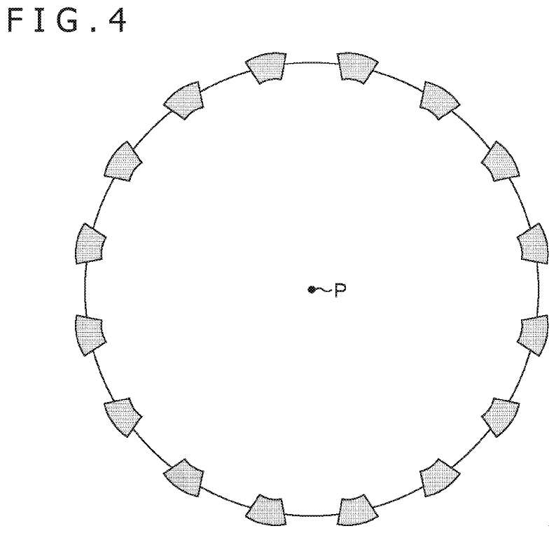

Note that, in the case of FIG. 3, the planar shape of each pixel 31 is a rectangular shape having sides in X and Y directions as in the case of common CMOS image sensors; however, the planar shape may be a fan shape (concentric circular shape), in conformance with their circular arrangement, with the plane center position P being the center of circle, as depicted in FIG. 4. Alternatively, the fan shape (concentric circular shape) with the plane center position P being the center of circle may be not a curved shape that has arcs on both the outer and inner circumference sides, but a polygon fan shape (concentric polygonal shape) that is approximated by straight lines.

Further, in FIG. 3, although no pixel 31 is disposed at the plane center position P of the pixel array section 11, i.e., at the center of the concentric circles, one pixel 31 may be disposed at the plane center position P.

### First Exemplary Arrangement of Pixel Drive Line 21 and Output Signal Line 22

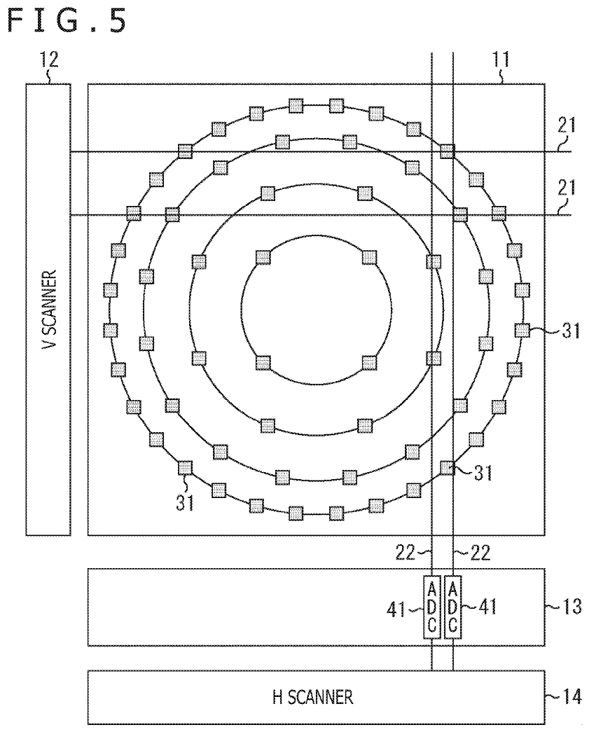

FIG. 5 illustrates a first exemplary arrangement of the pixel drive lines 21 and the output signal lines 22, in the case of the concentric arrangement of pixels 31.

In the first exemplary arrangement, the pixel drive lines 21 and the output signal lines 22 are disposed so as to linearly extend in the horizontal direction or the vertical direction, as in the case of common CMOS image sensors. The pixel drive lines 21 can be wired so as to linearly extend in the horizontal direction while the output signal lines 22 can be wired so as to linearly extend in the vertical direction. In the case of FIG. 5, only two lines of the pixel drive lines 21 and only two lines of the output signal lines 22 are depicted. However, of a plurality of the pixels 31 disposed on the circumferences in the pixel array section 11, one or more pixels 31 present at the same vertical position are driven by means of the same pixel drive line 21. Further, of a plurality of the pixels 31 disposed on the circumferences in the pixel array section 11, pixel signals of one or more pixels 31 present at the same horizontal position are transmitted by means of the same output signal line 22 to an ADC 41 of the AD conversion section 13. With the AD conversion section 13, one ADC (Analog-Digital Converter) 41 is disposed for one output signal line 22.

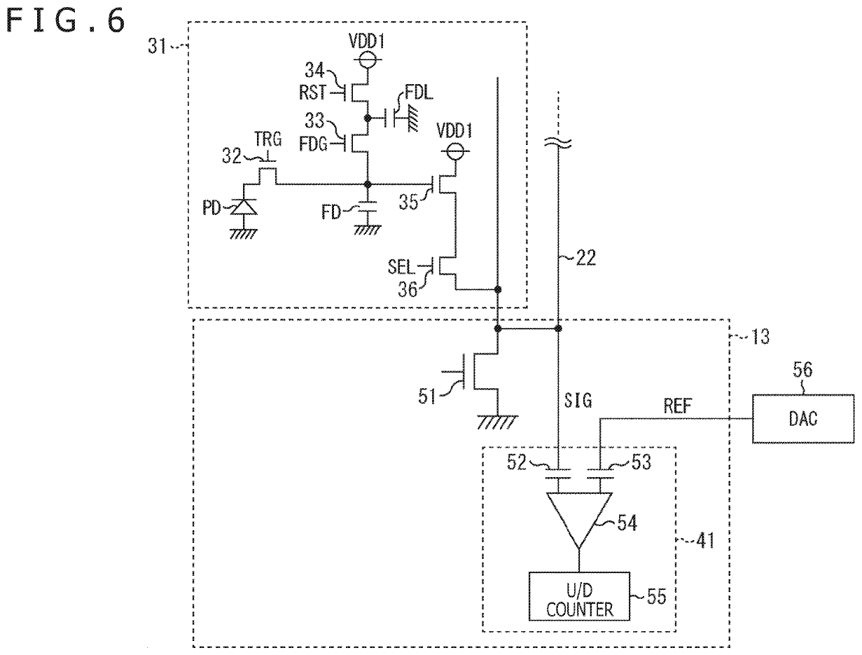

Here, with reference to FIG. 6, a description will be made regarding the configuration in detail of the pixel 31 and also the configuration of the AD conversion section 13 which processes the pixel signals fed from the pixel 31.

FIG. 6 is a detailed diagram depicting an exemplary configuration of the AD conversion section 13 and one pixel 31 in the pixel array section 11 which both are connected to one output signal line 22.

The pixel 31 includes a photodiode PD serving as a photoelectric conversion element, a transfer transistor 32, a floating diffusion region FD, an additional capacitance FDL, a switching transistor 33, a reset transistor 34, an amplification transistor 35, and a selection transistor 36. The transfer transistor 32, the switching transistor 33, the reset transistor 34, the amplification transistor 35, and the selection transistor 36 each include an N-type MOS transistor, for example.

The photodiode PD generates and accumulates electric charge (signal charge) according to an amount of received light.

When a transfer drive signal TRG supplied to its gate electrode becomes an active state, the transfer transistor 32 becomes a conductive state in response to the active state of the TRG, thereby transferring the electric charge accumulated in the photodiode PD to the floating diffusion region FD.

The floating diffusion region FD is a charge storage section which temporarily holds the electric charge transferred from the photodiode PD.

When an FD drive signal FDG supplied to its gate electrode becomes an active state, the switching transistor 33 becomes a conductive state in response to the active state of the FDG, thereby connecting the additional capacitance FDL to the floating diffusion region FD.

When a reset drive signal RST supplied to its gate electrode becomes an active state, the reset transistor 34 becomes a conductive state in response to the active state of the RST, thereby resetting the electric potential of the floating diffusion region FD. Note that, when the reset transistor 34 is turned into an active state, the switching transistor 33 is also turned into an active state simultaneously, which causes both the floating diffusion region FD and the additional capacitance FDL to be reset simultaneously.

When the amount of incident light is large at high illuminance, for example, the V scanner 12 turns the switching transistor 33 into an active state, thereby connecting the additional capacitance FDL to the floating diffusion region FD. This allows more electric charge to be accumulated at high illuminance.

In contrast, when the amount of incident light is small at low illuminance, the V scanner 12 turns the switching transistor 33 into an inactive state, thereby disconnecting the additional capacitance FDL from the floating diffusion region FD. This results in an increased conversion efficiency.

The amplification transistor 35 is such that its source electrode is connected to the output signal line 22 via the selection transistor 36, thereby being connected to the load MOS 51 serving as a constant current source. This constitutes a source follower circuit.

The selection transistor 36 is connected between the source electrode of the amplification transistor 35 and the output signal line 22. When a selection signal SEL supplied to its gate electrode becomes an active state, the selection transistor 36 becomes a conductive state in response to the active state of the SEL, thereby outputting a pixel signal SIG fed by the amplification transistor 35 to the output signal line 22.

The transfer transistor 32, the switching transistor 33, the reset transistor 34, and the selection transistor 36 of the pixel 31 are controlled by the V scanner 12. Each of the signal lines through which the transfer drive signal TRG, the FD drive signal FDG, the reset drive signal RST, and the selection signal SEL are transferred, corresponds to a corresponding one of the pixel drive lines 21 depicted in FIG. 1.

In the pixel circuit of FIG. 6, the additional capacitance FDL and the switching transistor 33 for controlling the connection of the FDL may be omitted; however, a high dynamic range can be achieved both by providing the additional capacitance FDL and by using it selectively according to the amount of incident light.

In the AD conversion section 13, both the ADC 41 and the load MOS 51 serving as a constant current source are disposed for one line of the output signal lines 22. Therefore, in the AD conversion section 13, the ADCs 41 and the load MOSs 51 are disposed such that the numbers of the former and latter are each equal to the number of lines of the output signal lines 22 disposed in the pixel array section 11.

The ADC 41 includes capacitive elements (capacitors) 52 and 53, a comparator (comparator) 54, and an up/down counter (U/D CNT) 55.

The pixel signal SIG output from the pixel 31 is inputted into the capacitive element 52 of the ADC 41 via the output signal line 22. On the other hand, into the capacitive element 53, a reference signal REF is inputted from the DAC (Digital to Analog Converter) 56 disposed outside the AD conversion section 13, with the reference signal REF having what is generally called a ramp (RAMP) waveform in which the level (voltage) varies in an inclined manner with the lapse of time.

Note that the capacitive elements 52 and 53 are intended to remove DC components from both the reference signal REF and the pixel signal SIG such that the comparator 54 can use only AC components of the both, in comparing the pixel signal SIG with the reference signal REF.

The comparator (comparator) 54 compares the pixel signal SIG with the reference signal REF and outputs the resulting difference signal to the up/down counter 55. For example, in the case where the reference signal REF is larger than the pixel signal SIG, a difference signal of Hi (High) is supplied to the up/down counter 55. In the case where the reference signal REF is smaller than the pixel signal SIG, a difference signal of Lo (Low) is supplied to the up/down counter 55.

The up/down counter (U/D counter) 55 counts down only while the difference signal of Hi is being supplied in a P-phase (Preset Phase) AD conversion period and counts up only while the difference signal of Hi is being supplied in a D-phase (Data Phase) AD conversion period. Then, the up/down counter 55 adds the down-count value in the P-phase AD conversion period to the up-count value in the D-phase AD conversion period and outputs the resulting added value as the pixel data after having been subjected to the CDS processing and AD conversion processing. Note that another method may be employed in which the counter counts up in the P-phase AD conversion period and counts down in the D-phase AD conversion period. The pixel data after having been subjected to the CDS processing and AD conversion processing are temporarily stored by the up/down counter 55 and are transferred to the signal processing section 16 at a predetermined timing, under the control of the H scanner 14.

### Second Exemplary Arrangement of Pixel Drive Line 21 and Output Signal Line 22

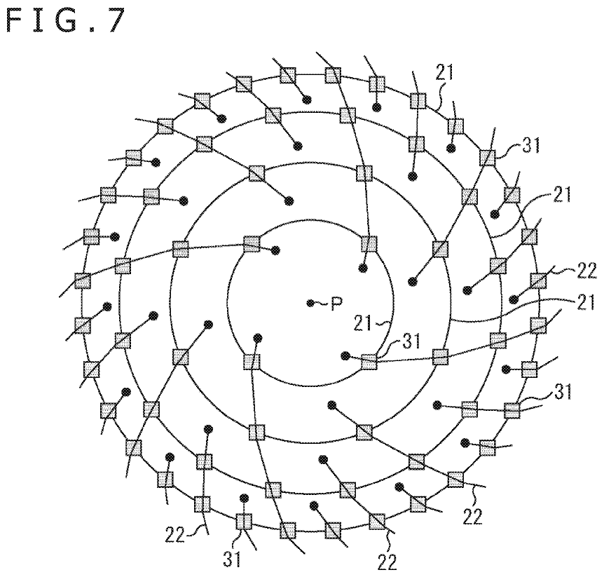

FIG. 7 illustrates a second exemplary arrangement of pixel drive lines 21 and output signal lines 22 in the concentric arrangement of the pixels 31.

In the second exemplary arrangement, the pixel drive line 21 is disposed for every unit of plural pixels 31 arranged on the circumference of a concentric circle that has the center of circle, i.e., a plane center position P of the pixel array section 11 and that has a predetermined radius r. In the case of FIG. 7, one pixel drive line 21 is disposed for four pixels 31 arranged on the circumference having a radius r1, and one pixel drive line 21 is disposed for eight pixels 31 arranged on the circumference having a radius r2. Further, one pixel drive line 21 is disposed for 16 pixels 31 arranged on the circumference having a radius r3, and one pixel drive line 21 is disposed for 32 pixels 31 arranged on the circumference having a radius r4. Note that, in FIG. 7, although the radii r1 to r4 are omitted to avoid complicating the figure, the arrangement of the pixels is similar to that of depicted in FIG. 3.

On the other hand, the output signal lines 22 are disposed along radial directions as follows: Each of the output signal lines 22 connects a pixel 31 arranged on the circumference of a concentric circle that is positioned on the center side (inner side), i.e., on the plane center position P side in the pixel array section 11, to other pixels 31 arranged on the circumferences of other concentric circles that are positioned radially outer than the above-described concentric circle. In other words, in the case where the plural pixels 31 are connected to one output signal line 22, the concentric circles, on the circumferences of which the respective pixels 31 are arranged, are concentric circles different from each other. Note that, as is clear from the figure, in the pixel array section 11, the number of the pixels arranged on the circumference of a concentric circle becomes large as the concentric circle becomes present at more to the outside. Therefore, there also exist output signal lines 22 each of which is connected to only one pixel arranged on the outermost circumference. In each of the output signal lines 22, a black circle marked on the center side (inner side) of the pixel array section 11 represents the edge on the inner side of the output signal line 22.

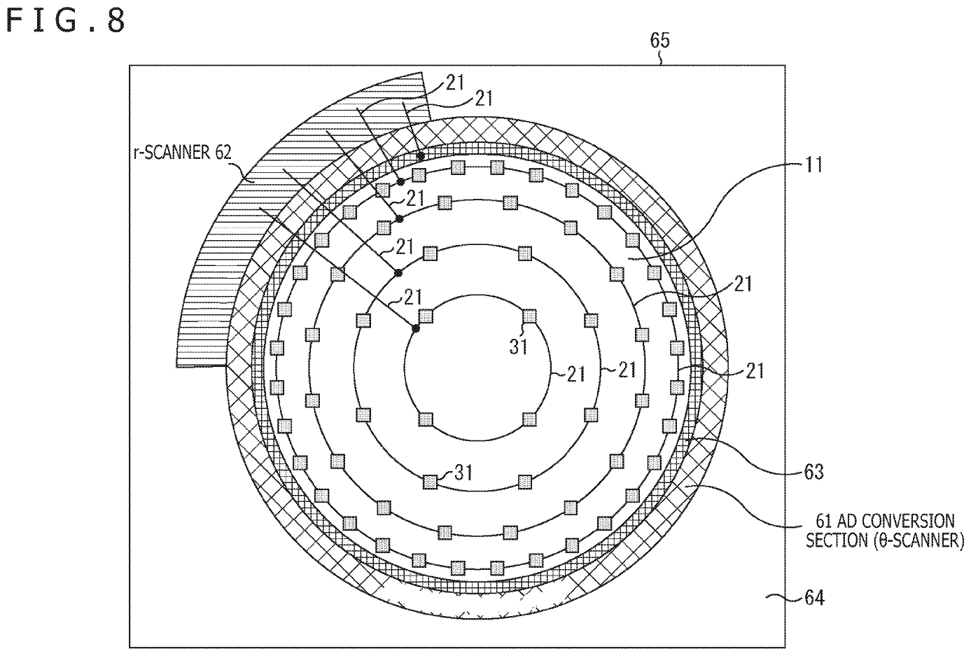

FIG. 8 is a diagram depicting an exemplary arrangement of a peripheral circuit section applicable to the second exemplary arrangement of the pixel drive lines 21 and the output signal lines 22.

Note that, in FIG. 8, the output signal lines 22 disposed along the radial directions are omitted.

For the second exemplary arrangement depicted in FIG. 7 in which the pixel drive lines 21 are each disposed circularly to drive a plurality of the pixels 31 arranged on the same circumference and in which the output signal lines 22 are disposed along the radial directions, the AD conversion section 61 is disposed, for example, on a circumference outside the pixel array section 11 in which a plurality of the pixels 31 is concentrically arranged. Then, further outside the AD conversion section 61, an r-scanner 62 to drive the pixels 31 is disposed. The r-scanner 62 corresponds to the V scanner 12 of FIG. 1, and the AD conversion section 61 corresponds to the AD conversion section 13 and the H scanner 14 of FIG. 1. Although partly omitted in FIG. 7, the pixel drive lines 21 include, as depicted in FIG. 8, both the wirings formed circularly to provide an interconnection between plural pixels 31 and the wirings formed radially to be connected to the r-scanner 62.

Further, in FIG. 8, an OPB region 63 is formed, for example, at the outermost circumference of the circularly-formed pixel array section 11, in other words, it is formed at an area that is in the pixel array section 11 and closest to the AD conversion section 61. The OPB region 63 is a region where OPB pixels are disposed; such pixels are each a pixel 31 for detecting black level and are shielded from light so as not to receive incident light.

With a semiconductor substrate 65 having a rectangular shape, in a region 64 further outside the pixel array section 11, the AD conversion section 61, and the r-scanner 62 which are formed in a circle or fan shape, other circuits are disposed. specifically, the system controller 15, the signal processing section 16, the data storage section 17, the input/output terminals 18, and the like are disposed therein.

As described above, in conformance with the pixel drive lines 21 and the output signal lines 22 which are disposed circularly and radially, both the r-scanner 62 for driving the pixels 31 and the AD conversion section 61 for performing the AD conversion processing and the like to the pixel signals may also be disposed circularly. This arrangement can be achieved by taking the projection region of a fisheye lens depicted in FIG. 2 into consideration, which in turn can provide a differential region between the arrangement and the rectangular semiconductor substrate 65, allowing an efficient arrangement of other circuits (elements) in such a differential region.

### <Pixel Cross-Sectional Structure>

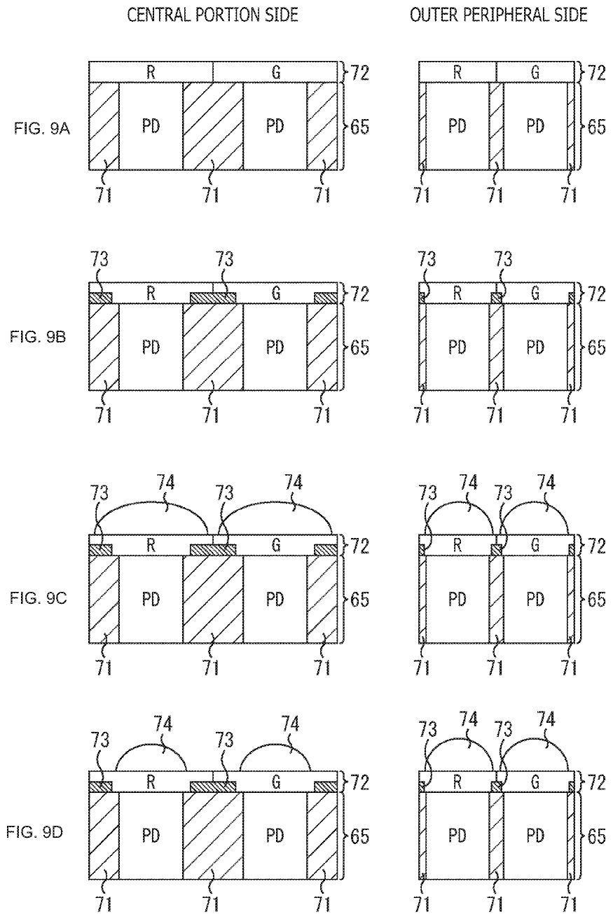

FIG. 9 is a cross-sectional diagram depicting cross-sectional structures of the pixels 31 arranged concentrically. In FIG. 9, among the pixels 31 arranged concentrically, there are depicted the cross-sectional views of pixels located on the center side and closer to the plane center position P of the pixel array section 11 and of pixels located on the outer peripheral side.

For example, as depicted in sub-diagram A of FIG. 9, for the semiconductor substrate 65, a photodiode PD is disposed for each pixel and a pixel separation region 71 is disposed between the photodiodes PD of adjacent pixels 31. The pixel separation region 71 is formed of an insulating film such as P-Well, DTI (Deep Trench Isolation), SiO2, or the like. Of the upper surface and the lower surface of the semiconductor substrate 65, a color filter 72 is formed on the incident surface side from which incident light enters there, with the filter being capable of transmitting any of R (Red), G (Green), and B (Blue) lights.

As can be seen by comparing between both cross-sectional views, i.e., one on the center side and one on the outer peripheral side, of sub-diagram A of FIG. 9, the formation regions of the photodiodes PD are the same for every pixel 31, and the spaces between adjacent pixels 31 are made different by changing the widths in a circumference direction of the pixel separation regions 71. Making the formation regions of the photodiodes PD identical at every location in the pixel array section 11 results in ease of designing and manufacturing processes.

In the case where an inter-pixel light-shielding film 73 is formed for preventing incident light from entering neighboring pixels, as depicted in sub-diagram B of FIG. 9, such an inter-pixel light-shielding film 73 is formed on the upper surface of the pixel separation region 71. The upper surface of the pixel separation region 71 is on the incident surface side of the semiconductor substrate 65 and is provided with the color filter 72. It is sufficient if the material of the inter-pixel light-shielding film 73 is any material capable of blocking light. Examples of such materials are tungsten (W), aluminum (Al), copper (Cu), and any other metal. Disposing the inter-pixel light-shielding film 73 allows an improvement in difference in sensitivity between on the center side and on the outer peripheral side.

In addition, on the upper surface of the color filter 72, an on-chip lens 74 for condensing the incident light to the photodiode PD may be disposed on a per unit of pixel 31 basis. In this case, as depicted in sub-diagram C of FIG. 9, the on-chip lenses 74 may be such that the lenses are formed to have different curvatures between the pixels, i.e., pixels on the center side and pixels on the outer peripheral side, according to the spaces between neighboring pixels. Alternatively, the on-chip lenses 74 may be formed to have the same curvature for all the pixels, as depicted in sub-diagram D of FIG. 9. In the case where the curvatures of the on-chip lenses 74 are made the same for all the pixels, it brings about ease of designing and manufacturing processes.

Note that, in sub-diagrams C and D of FIG. 9, the plane center of the photodiode PD and the plane center position of the on-chip lens 74 coincide with each other in every pixel 31 on both the center side and the outer peripheral side. However, with a fisheye lens, since an incident angle of the principal ray of incident light becomes large on the outer peripheral side, the on-chip lenses 74 may be disposed in an arrangement for pupil correction.

In the case where pupil correction is performed, since the incident angle of the principal ray of incident light coming from an optical lens (not depicted) is 0 degrees at the central portion of the pixel array section 11, the pupil correction is not necessary there, and thus the center of the photodiode PD coincides with the centers of the color filter 72 and the on-chip lens 74.

On the other hand, at the outer peripheral portion of the pixel array section 11, since the incident angle of the principal ray of incident light coming from the optical lens is a predetermined angle according to the lens design, the pupil correction is performed. That is, the centers of the color filter 72 and the on-chip lens 74 are disposed to be shifted from the center of the photodiode PD towards the center of the pixel array section 11. The amount of the shift between the center position of the photodiode PD and the center positions of the color filter 72 and the on-chip lens 74 becomes larger at a closer position to the outer periphery of the pixel array section 11. Then, according to the shifts of the color filter 72 and the on-chip lens 74, the position of the inter-pixel light-shielding film 73 shifts greater toward the center at a closer position to the outer periphery of the pixel array section 11.

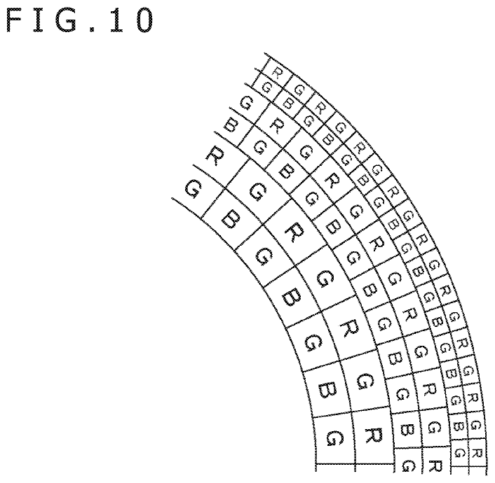

FIG. 10 is a plan view depicting an exemplary arrangement of the color filters 72.

The color filters 72 may be configured, as depicted in FIG. 10, such that the color filters 72 are disposed in a Bayer array, that is, the color filters 72 capable of transmitting G, R, B, and G lights through them are arranged for 4=2×2 adjacent pixels. However, the exemplary arrangement of the color filters 72 is not limited to the Bayer array, but may be any other arrangement. For example, the 4=2×2 adjacent pixels may include a pixel 31 provided with no color filter 72 or a pixel 31 provided with a filter capable of transmitting infrared light through it. Moreover, according to the location of the pixel 31 arranged concentrically in the pixel array section 11, the arrangement of the color filters 72 formed thereon may differ. Furthermore, there is a possibility of the configuration in which no color filter 72 is formed over the entire region of the pixel array section 11. For example, in the case where the solid-state imaging apparatus 1 is of a vertical spectroscopy type in which R, G, and B lights are photoelectrically converted on a single pixel basis, no color filters 72 are formed. With the solid-state imaging apparatus 1 of a vertical spectroscopy type, for example, G light is photoelectrically converted by a photoelectric conversion film disposed on the outer side of the semiconductor substrate 65, and B and R lights are photoelectrically converted by a first photodiode PD and a second photodiode PD, respectively, which are formed in the semiconductor substrate 65 by multilayering in the depth direction.

### Exemplary Configuration in which ADC is Disposed on a Per Unit of Pixel Basis

In the first and second exemplary arrangements described above, one ADC 41 is disposed for a plurality of the pixels 31 connected to one output signal line 22; however, another configuration may be employed in which the ADC 41 is disposed on a per unit of one-pixel basis.

Hereinafter, a description will be made regarding the configuration in which the ADC 41 is disposed for each pixel. The ADC 41 in the case of being disposed for each pixel has a configuration different from that of the ADC 41 illustrated in FIG. 6.

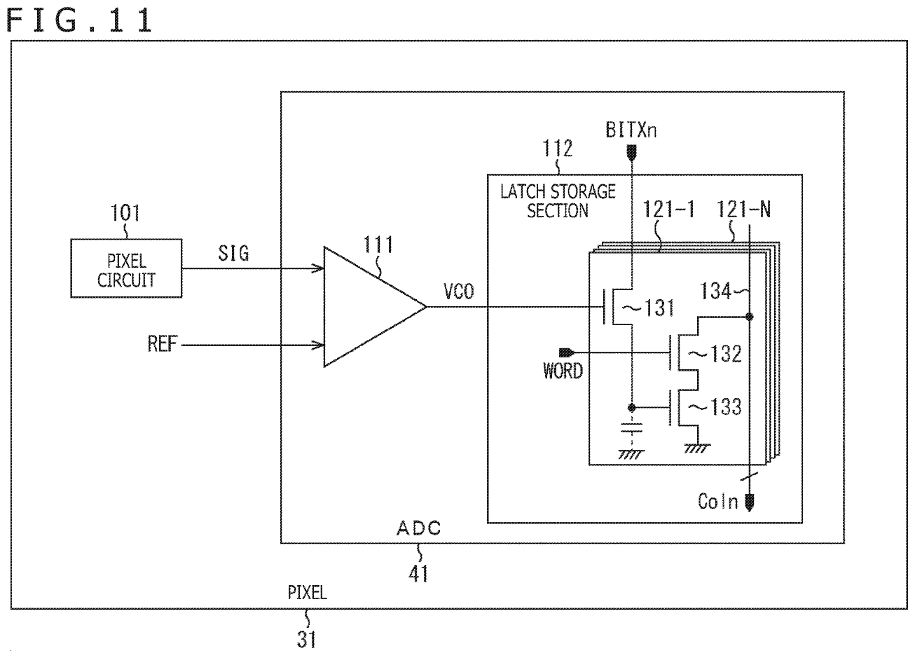

The pixel 31 includes, as depicted in FIG. 11, a pixel circuit 101 and an ADC 41 in the inside of the pixel. The pixel circuit 101 includes a photoelectric conversion section that generates and accumulates a charge signal according to the amount of received light and outputs, to the ADC 41, an analog pixel signal SIG obtained by the photoelectric conversion section. The detailed configuration of the pixel circuit 101 is similar to that of the pixel 31 described in FIG. 6, and thus its description is omitted. The ADC 41 converts, into a digital signal, the analog pixel signal SIG fed from the pixel circuit 101.

The ADC 41 includes a comparator 111 and a latch storage section 112. The comparator 111 compares the pixel signal SIG to a reference signal REF fed from the DAC 56 (FIG. 6) and outputs an output signal VCO as a signal indicating the result of the comparison. The comparator 111 inverts the output signal VCO when the reference signal REF and the pixel signal SIG become the same (voltage).

To the latch storage section 112, a code value BITXn (n=an integer of 1 to N) indicating the time at that time is input, as an input signal. Then, in the latch storage section 112, the code value BITXn of the time when the output signal VCO of the comparator 111 is inverted is held, and is then read out as an output signal Coln. With this configuration, the ADC 41 outputs a digital value obtained by digitizing the analog pixel signal SIG into N bits.

As depicted in the circuit diagram of FIG. 11, the latch storage section 112 is provided with N pieces of latch circuits (data storage section) 121-1 to 121-N corresponding to the N bits, i.e., the number of AD conversion bits. Note that, in the following, the N pieces of latch circuits 121-1 to 121-N will be simply described as the latch circuit 121 unless otherwise they need to be particularly distinguished.

To the gate of a transistor 131 of each of the N pieces of latch circuits 121-1 to 121-N, the output signal VCO of the comparator 111 is inputted.

To the drain of the transistor 131 of the latch circuit 121-n for the nth bit, a code input signal (code value) BITXn of 0 or 1, which indicates the time of that time, is inputted. The code input signal BITXn is, for example, a bit signal such as a Gray code. In the latch circuit 121-n, data LATn are stored which are ones at the time when the output signal VCO of the comparator 111 fed to the gate of the transistor 131 is inverted.

To the gate of the transistor 132 of the latch circuit 121-n for the nth bit, a read control signal WORD is inputted. When it comes to a read timing of the latch circuit 121-n for the nth bit, the control signal WORD becomes Hi, and thus an nth bit latch signal (code output signal) Coln is output from a latch signal output line 134.

Such a configuration as described above of the latch storage section 112 allows the ADC 41 to operate as an integration-type AD converter.

The configuration in which the ADC 41 is disposed on a per unit of one-pixel basis, allows the solid-state imaging apparatus 1 to be formed in a laminated structure of three semiconductor substrates.

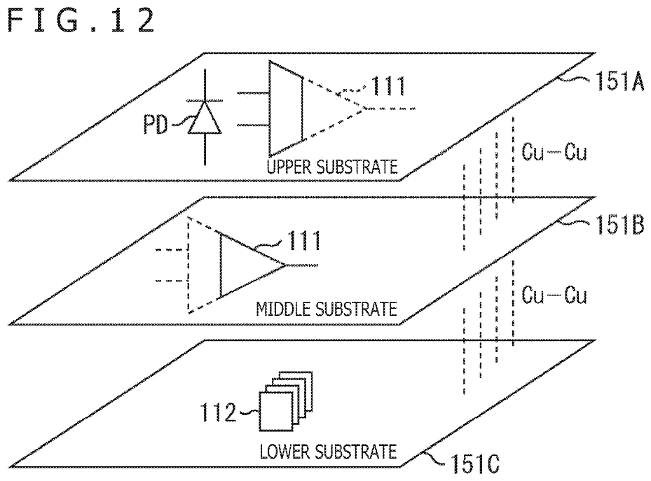

FIG. 12 is a conceptual diagram depicting the case of the solid-state imaging apparatus 1 being formed in the laminated structure of three semiconductor substrates.

The solid-state imaging apparatus 1 is formed by laminating three semiconductor substrates 151: an upper substrate 151A, a middle substrate 151B, and a lower substrate 151C.

In the upper substrate 151A, at least both the pixel circuit 101 including the photodiode PD and a part of the circuit of the comparator 111, are formed. In the lower substrate 151C, at least the latch storage section 112 including not smaller one latch circuit 121, is formed. In the middle substrate 151B, the rest of the circuit of the comparator 111 which is not disposed in the upper substrate 151A, is formed. The upper substrate 151A and the middle substrate 151B are joined to each other, for example, through metallic bonds such as Cu—Cu bonds or any other bond; the middle substrate 151B and the lower substrate 151C are joined to each other in the same manner.

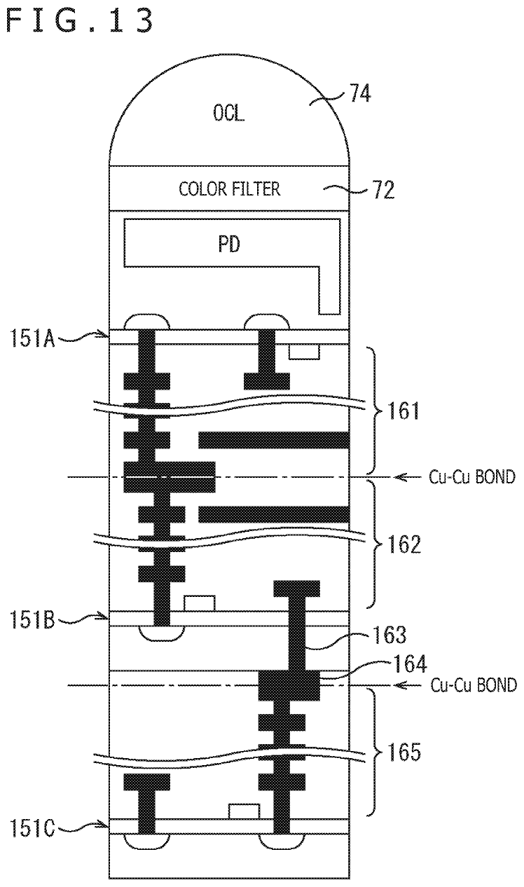

FIG. 13 is a schematic cross-sectional diagram depicting the case of the solid-state imaging apparatus 1 including the three semiconductor substrates 151.

The upper substrate 151A is of a back-illuminated type such that the photodiode PD, the color filter 72, the on-chip lens (OCL) 74, and the like are formed on the back-surface side of the substrate, opposite to the front-surface side on which a wiring layer 161 is formed.

The wiring layer 161 of the upper substrate 151A is bonded to a wiring layer 162 on the front-surface side of the middle substrate 151B by Cu—Cu bonding.

The middle substrate 151B is bonded to the lower substrate 151C by Cu—Cu bonding between a wiring layer 165 formed on the front-surface side of the lower substrate 151C and a connection wiring 164 of the middle substrate 151B. The connection wiring 164 of the middle substrate 151B is connected to the wiring layer 162 on the front-surface side of the middle substrate 151B with a through electrode 163.

In the wiring layer 165 formed on the front-surface side of the lower substrate 151C, there are also disposed the following parts including the signal processing section 16 to perform a predetermined signal processing such as grayscale correction processing of the image data having been subjected to an AD conversion by the ADC 41, and a circuit of the data storage section 17 to temporarily store data that are necessary in performing the signal processing by the signal processing section 16. In addition, on the back-surface side of the lower substrate 151C, the input/output terminals 18 formed in bumps or the like are disposed.

### 3. Second Exemplary Configuration of Pixel Array Section

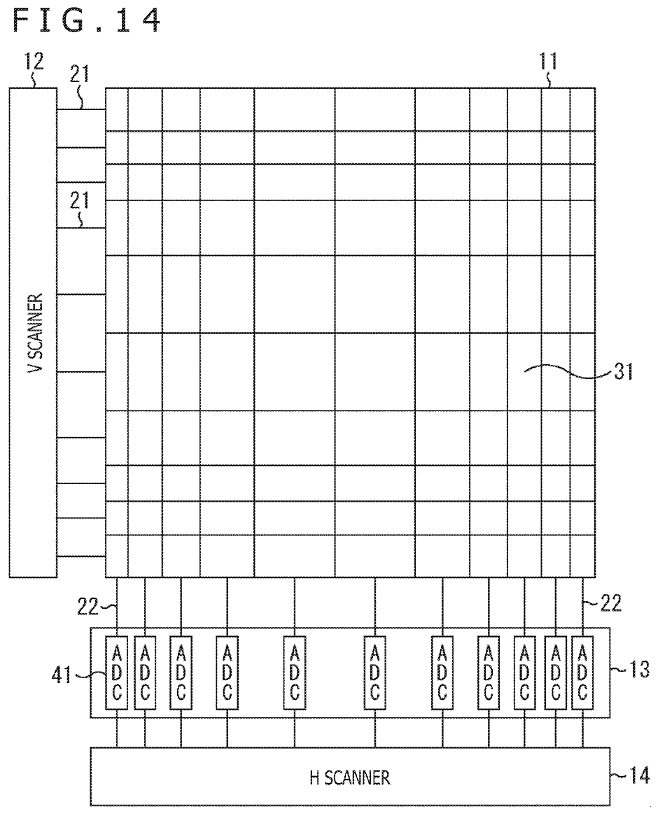

FIG. 14 is a plan view depicting a second exemplary configuration of the pixel array section 11.

Note that, in FIG. 14, there are depicted only portions corresponding to those depicted in FIG. 5 of the first exemplary configuration; the system controller 15, the signal processing section 16, and the like are omitted. In the second exemplary configuration depicted in FIG. 14, parts corresponding to those of the first exemplary configuration are designated by the same symbols, and their explanations will be appropriately omitted.

In the first exemplary configuration described above, the pixels 31 are arranged in concentrically, with the plane center position P of the pixel array section 11 being the center. However, in the second exemplary configuration, the pixels are arranged two-dimensionally in a matrix as in the case of common image sensors. However, the size of the pixel 31 is large at the central portion of the pixel array section 11 and becomes gradually smaller at a greater distance away from there toward the peripheral portion. With this configuration, a plurality of the pixels 31 is arranged such that its pixel pitch becomes smaller at a greater distance away from the central portion toward the outer peripheral portion.

For all the pixels 31 arranged in the matrix, the pixel drive lines 21 are wired on a unit of row basis, and the output signal lines 22 are wired on a unit of column basis. Since the pixel sizes are different in different locations in the pixel array section 11, plural pixel drive lines 21 arranged in the vertical direction are positioned in a non-equidistant arrangement. Likewise, plural output signal lines 22 arranged in the horizontal direction are also positioned in a non-equidistant arrangement. More specifically, the pixel drive lines 21 and the output signal lines 22 are disposed such that their space between neighboring lines becomes smaller at a greater distance away from the central portion of the pixel array section 11 toward the outer peripheral portion.

The AD conversion section 13 includes plural ADCs 41, and the respective ADCs 41 are disposed corresponding to the respective pixel columns of the pixel array section 11. Consequently, the solid-state imaging apparatus 1 of the second exemplary configuration is a CMOS image sensor that is of what is generally called a column AD system in which the ADC 41 is disposed for every pixel column.

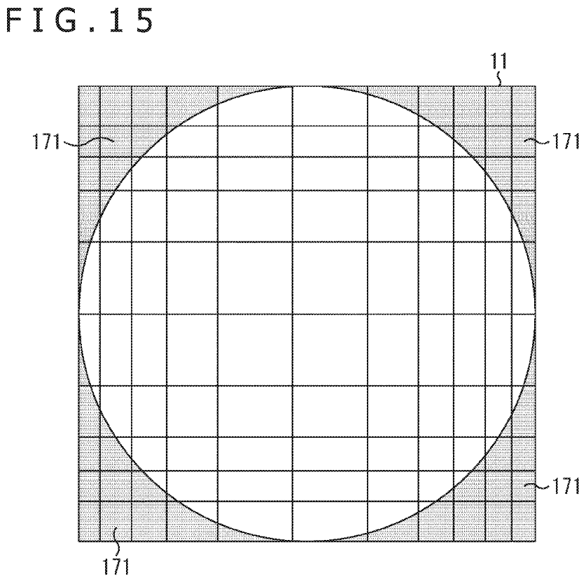

Obviously, the V scanner 12 is not only capable of performing all-pixels-read-out drive in which all pixels in the pixel array section 11 are driven and the resulting pixel signals are read out, but also capable of performing partial drive in which only a partial area of the pixel array section 11 is driven and the resulting pixel signals are read out. As depicted in FIG. 2, in the case of photographing by using a fisheye lens, the projection region onto which the image of a subject is projected is a circular region. Therefore, pixels 31 located in non-projection regions 171 onto which no image of the subject is projected may be configured not to be driven regarding pixel drive for receiving-light and read-out. Such non-projection regions are indicated by gray areas in FIG. 15. Alternatively, the pixels 31 in the non-projection regions 171 may be an OPB region in which OPB pixels are arranged.

In the pixel array section 11 of the second exemplary configuration, as depicted in FIG. 14, the sizes of the pixels 31 may be changed according to their locations in the pixel array section 11, thereby changing the pixel pitches according to the location in the pixel array section 11. Alternatively, the configuration may be such that sub-pixels having the same size are formed and such that pixel signals of the sub-pixels are combined and output on a per unit of a set of sub-pixels basis. Then, the unit of the set of the sub-pixels are changed, thereby substantially changing the pixel pitches according to the location in the pixel array section 11.

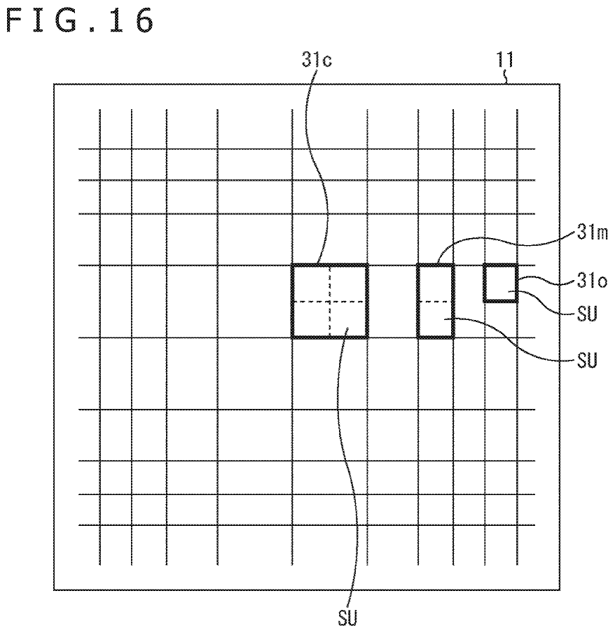

Specifically, for example, the pixel array section 11 is configured by arranging sub-pixels SU having the same size in a matrix evenly or substantially evenly, as depicted in FIG. 16. A pixel 31c at the central portion of the pixel array section 11 includes four sub-pixels SU, a pixel 31m at the middle portion includes two sub-pixels SU, and a pixel 31o at the outer peripheral portion includes one sub-pixel SU.

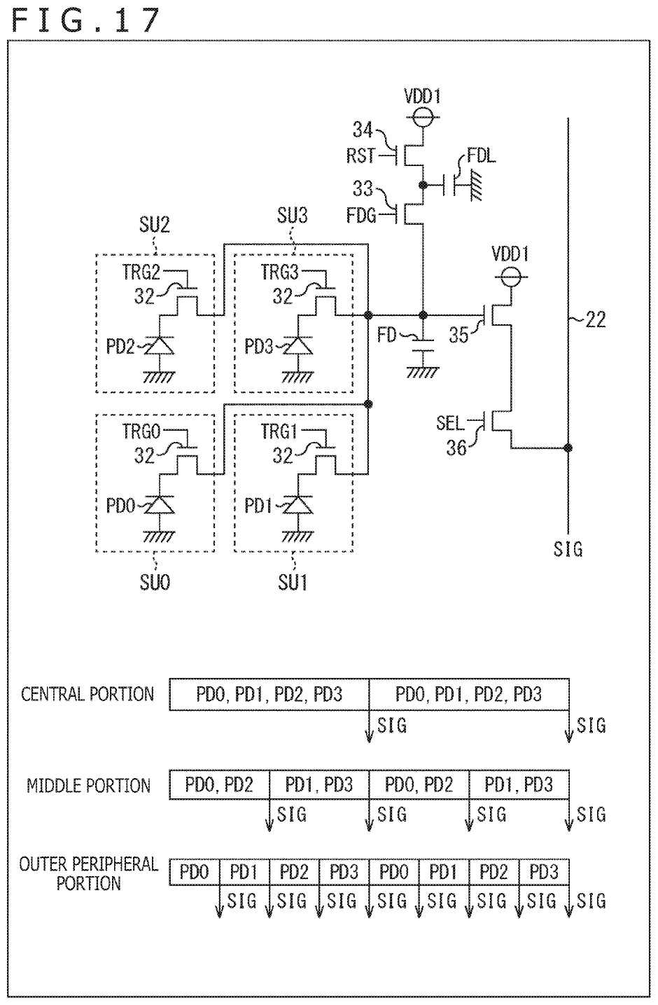

FIG. 17 is a diagram depicting a pixel circuit in the case where the sub-pixels SU are arranged in a matrix.

A pixel circuit in the case where the sub-pixels SU are arranged in the matrix may employ a shared by pixel structure in which a plurality of pixel transistors is shared.

That is, in the shared by pixel structure, as depicted in FIG. 17, both the photodiode PD and the transfer transistor 32 are formed and disposed for every sub-pixel SU. On the other hand, the floating diffusion region FD, the additional capacitance FDL, the switching transistor 33, the reset transistor 34, the amplification transistor 35, and the selection transistor 36 are shared by the four sub-pixels SU.

Here, the four sub-pixels SU that share the floating diffusion region FD, the amplification transistor 35, etc., are all distinguished from each other, and so designated as the sub-pixels SU0 to SU3. The photodiodes PD included in the respective four sub-pixels SU and the transfer drive signals TRG supplied to the transfer transistors 32 are also distinguished from each other, that is, designated as the photodiodes PD0 to PD3 and the transfer drive signals TRG0 to TRG3.

In the pixel 31c at the central portion of the pixel array section 11, the transfer drive signals TRG0 to TRG3 supplied to the four sub-pixels SU are simultaneously controlled to Hi, and thus the four transfer transistors 32 are simultaneously turned ON. With this configuration, a signal which is generated by combining electric charges of light received by the photodiodes PD0 to PD3 is output as a pixel signal SIG.

In the pixel 31m at the middle portion of the pixel array section 11, for example, the transfer drive signals TRG0 and TRG2 for two, a unit, of the four sub-pixels SU become Hi simultaneously; then, a signal which is generated by combining electric charges of light received by the photodiodes PD0 and PD2 is output as a pixel signal SIG. After that, the transfer drive signals TRG1 and TRG3 become Hi simultaneously; then, a signal which is generated by combining electric charges of light received by the photodiodes PD1 and PD3 is output as a pixel signal SIG.

In the pixel 31o at the outer peripheral portion of the pixel array section 11, for example, the transfer drive signals TRG0, TRG1, TRG2, and TRG3 for the four sub-pixels SU become Hi one by one and sequentially in this order; then, signals which are generated by combining electric charges of light received by the photodiodes PD0, PD1, PD2, and PD3 are output sequentially as a pixel signal SIG.

As described above, the number (unit of combining) of signals, which are obtained by the sub-pixels SU and then combined together, can be changed according to the location in the pixel array section 11, thereby substantially changing the pixel pitch in the pixel array section 11. In this case as well, since the pixel pitch is large at the central portion of the pixel array section 11 and becomes smaller at a greater distance away from there toward the outer peripheral portion (circumferential portion), the pitch varies in a similar manner to that of an image projected by a fisheye lens. This configuration makes it possible to improve sense of resolution at outer peripheral portions of the image photographed by using a fisheye lens.

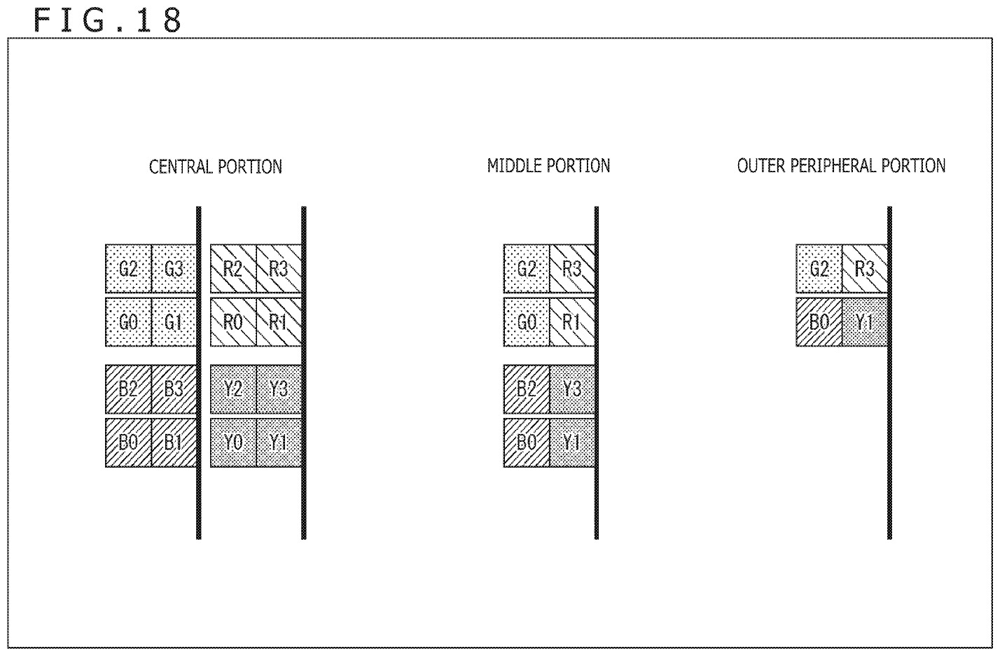

FIG. 18 is a diagram depicting an exemplary arrangement of color filters in each sub-pixel SU in the case where the pixel pitch is changed by changing the unit of combining of the sub-pixels SU.

The colors of the color filters 72 are all arranged in units of combining of the sub-pixels SU.

For example, suppose the case where the color filters 72 are arranged in a Bayer array and where a repetition unit of G, R, B, and G in the Bayer array is expressed as a repetition unit of G, R, B, and Y in order to distinguish the two symbols of G. Then, at the central portion of the pixel array section 11, the color filters 72 of G, R, B, or Y are disposed for every four (2 rows×2 columns) sub-pixels SU. At the middle portion of the pixel array section 11, the color filters 72 of G, R, B, or Y are disposed for every two (2 rows×1 column) sub-pixels SU. At the outer peripheral portion of the pixel array section 11, the color filters 72 of G, R, B, or Y are disposed for every one sub-pixel SU.

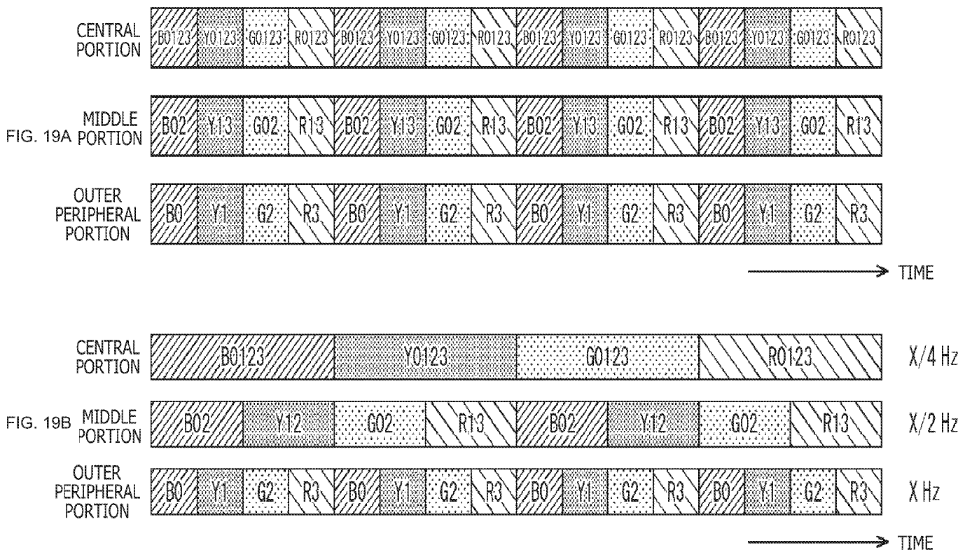

FIG. 19 is a diagram depicting drive timing charts in the case where the pixel pitch is changed by changing the unit of combining of the sub-pixels SU. In sub-diagrams A and B of FIG. 19, the horizontal direction (horizontal axis) represents the time axis.

Sub-diagram A of FIG. 19 depicts the drive timing chart illustrating a first drive method.

“B0123” of FIG. 19 represents the outputting of a pixel signal SIG according to the amount of light received by the four sub-pixels SU provided with the color filters 72 of B0, B1, B2, and B3 depicted in FIG. 18. “B02” represents the outputting of a pixel signal SIG according to the amount of light received by the two sub-pixels SU provided with the color filters 72 of B0 and B2 depicted in FIG. 18. “B0” represents the outputting of a pixel signal SIG according to the amount of light received by the one sub-pixel SU provided with the color filter 72 of B0 depicted in FIG. 18. The same is true for other colors of G, R, and Y.

The first drive method is a drive of reading at the same frequency, in which the output timings of pixel signals SIG are the same even if their units of combining are different. That is, the pixel signals SIG are read out at the same timing in all the following cases: The case of the pixel signal SIG output from the four sub-pixels SU at the central portion of the pixel array section 11, the case of the pixel signal SIG output from the two sub-pixels SU at the middle portion of the pixel array section 11, and the case of the pixel signal SIG output from one sub-pixel SU at the outer peripheral portion of the pixel array section 11.

Sub-diagram B of FIG. 19 depicts the drive timing chart illustrating a second drive method.

The second drive method is a drive of reading at variable frequencies in which the output timings of pixel signals SIG are different according to different units of combining. The larger the pixel size, the longer the read period of the pixel signal SIG is. Specifically, during one period of reding out the pixel signal SIG of one pixel including the four sub-pixels SU at the central portion of the pixel array section 11, the pixel signals SIG of two pixels are read out at the middle portion of the pixel array section 11, and the pixel signals SIG of four pixels are read out at the outer peripheral portion of the pixel array section 11. Assuming that the read frequency at the outer peripheral portion is X [Hz], then the read frequency at the middle portion is X/2 [Hz] and the read frequency at the central portion is X/4 [Hz].

As so far described above, according to the first and second exemplary configurations of the pixel array section 11, since the pixel pitch is large at the central portion of the pixel array section 11 and becomes smaller at a greater distance away from there toward the outer peripheral portion (circumferential portion), the pitch changes in a similar manner to that of an image projected by a fisheye lens. This configuration makes it possible to improve sense of resolution at outer peripheral portions of the image photographed by using a fisheye lens. The pixels are disposed so as to match the projection characteristics of the lens, which allows the pixels to match the performance of the lens, resulting in the formation of an image close to the real image, that is, an image with less feeling of incongruity.

### 4. Real-Time Control of Drive Area

Next, a description will be made regarding real-time control of a drive area performed in the solid-state imaging apparatus 1.

The solid-state imaging apparatus 1 is capable of performing control so that, among a plurality of the pixels 31 constituting the pixel array section 11, driving of pixels 31 not used for forming an image is halted.

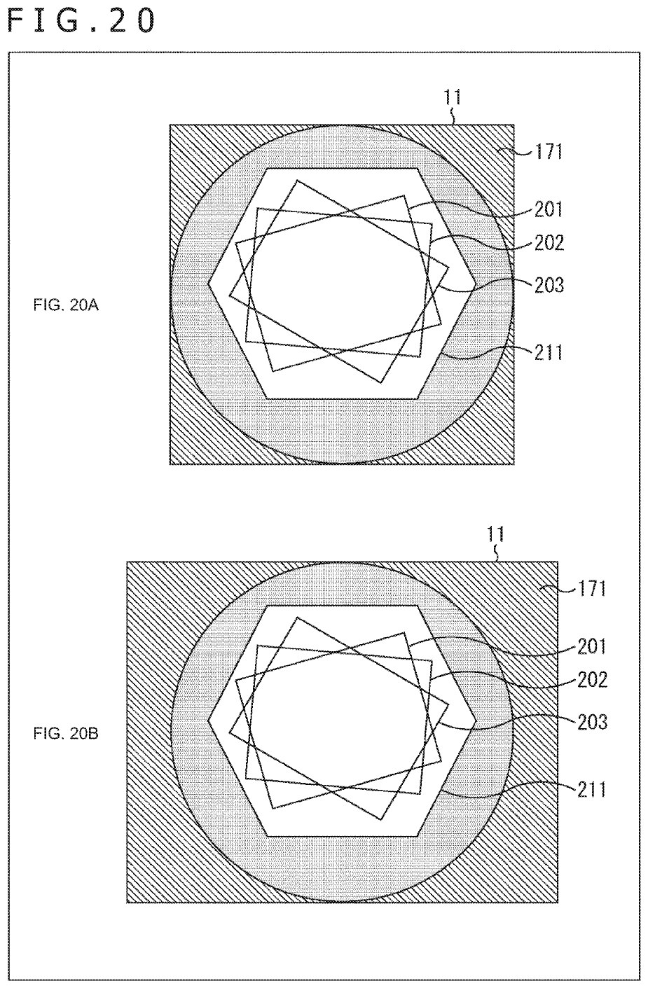

For example, for the pixel array section 11 in a square region of sub-diagram A of FIG. 20, the solid-state imaging apparatus 1 performs the control so that the driving is halted of pixels 31 in non-projection regions 171 at the four corners indicated by hatching.

Further, for example, in the case where the in-use region of an image dynamically changes as illustrated by regions 201 to 203 of sub-diagram A of FIG. 20, on the basis of sensor data obtained by such as a gyro sensor, like a phenomenon in imaging under stabilization correction, the solid-state imaging apparatus 1 adds a predetermined margin to the dynamically-changing regions 201 to 203 to determine an effective area 211, and then performs control such that the drive of the pixels 31 outside the effective area 211 is halted. The region of the margin may be determined (modified) according to operation modes such as a bicycle mode, a walking mode, a running mode or the like, for example.

Sub-diagram B of FIG. 20 depicts an example of the non-projection region 171 and the effective area 211 in the case where the shape of array of the pixel array section 11 is rectangular. In the case where the shape of array of the pixel array section 11 is rectangular, since the non-projection region 171 includes not only the four corners but also the left and right regions, halting of their drive enhances the advantageous effect on a reduction in electric power consumption.

Note that the arrangement configurations of the pixels 31 in the pixel array sections 11 of sub-diagrams A and B of FIG. 20 may be any of the first exemplary configuration depicted in FIG. 3 and the second exemplary configuration depicted in FIG. 14.

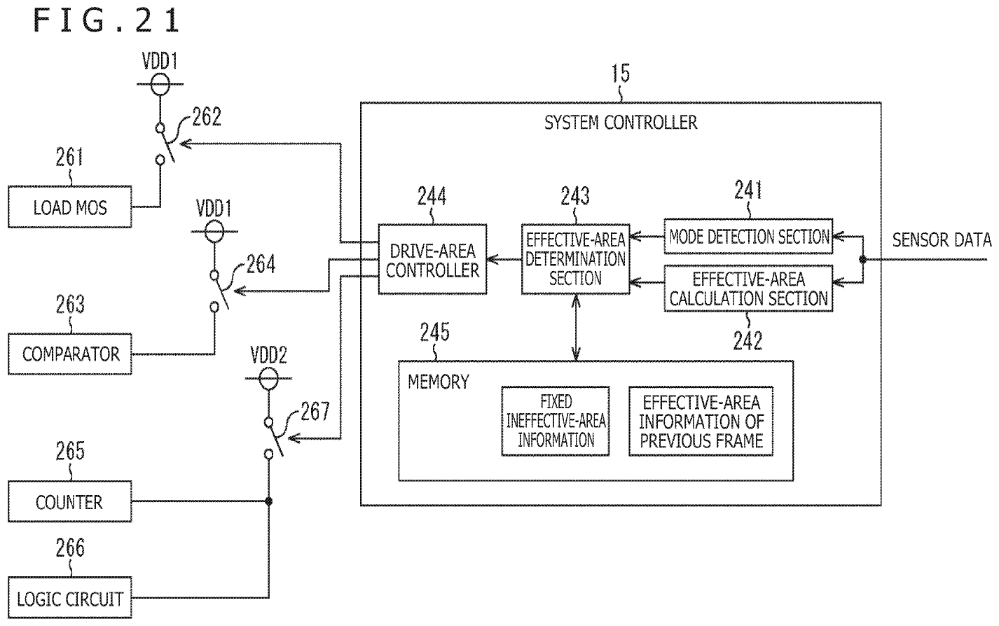

FIG. 21 is a block diagram illustrating the case where the system controller 15 controls a drive area for each frame (real-time control).

In relation to the real-time control of the drive area, the system controller 15 includes a mode detection section 241, an effective-area calculation section 242, an effective-area determination section 243, a drive-area controller 244, and a memory 245.

Sensor data output from a gyro sensor, an acceleration sensor, and the like are supplied to the system controller 15 via the input/output terminals 18.

The mode detection section 241 detects an operation mode on the basis of the supplied sensor data, and supplies the detected operation mode to the effective-area determination section 243. Such an operation mode is a bicycle mode, a walking mode, a running mode, or the like, for example, which is determined according to the shaking state detected from the sensor data.

The effective-area calculation section 242 calculates an effective area of a current frame on the basis of the supplied sensor data, and supplies the result to the effective-area determination section 243.

The effective-area determination section 243 determines an effective area of the current frame, by adding a predetermined margin according to the operation mode determined by the mode detection section 241, to the effective area of current frame which is supplied from the effective-area calculation section 242. Moreover, the effective-area determination section 243 acquires effective-area information of a previous frame, with the information being stored in the memory 245, and thereby determines a change area from the effective area of the previous frame to the effective area of the current frame. Then, the effective-area determination section 243 supplies, to the drive-area controller 244, information regarding the thus-determined change area of the effective area. Furthermore, the effective-area determination section 243 causes the memory 245 to store the information indicating the effective area of the current frame, as information for the next frame regarding the effective area of the previous frame.

As described above, in the case where the drive area is controlled for every frame, in the second and later frames, information regarding a change region of an effective area is supplied from the effective-area determination section 243 to the drive-area controller 244. However, in the first frame, information that indicates the whole of the effective area in the pixel array section 11 and that includes information regarding fixed ineffective areas stored in the memory 245, is supplied from the effective-area determination section 243 to the drive-area controller 244. The information regarding the fixed ineffective areas is information associated with preset fixed ineffective areas, such as information regarding the non-projection regions 171 at the four corners of the pixel array section 11, for example.

The drive-area controller 244 performs control on the basis of the information indicating the effective area of the current frame such that the drive of ineffective areas other than the effective area is halted.

For example, the drive-area controller 244 turns off a switch 262 of a power supply to a load MOS 261 in the ineffective areas, turns off a switch 264 of a power supply to a comparator 263 in the ineffective areas, and turns off a switch 267 of a power supply to a counter 265 and a logic circuit 266 in the ineffective areas. The load MOS 261 corresponds to the load MOS 51 of FIG. 6, for example; the comparator 263 corresponds to the comparator 54 of FIG. 6, for example; the counter 265 and the logic circuit 266 correspond to the up/down counter 55 of FIG. 6, the signal processing section 16 of FIG. 1, and the like, for example.

Further, in order to halt the drive of the ineffective areas, the drive-area controller 244 may perform not the control such that the power supply is turned off, but control such that the supply of a timing signal (clock signal) is turned off.

That is, in order to halt the drive of the pixels 31 in the ineffective areas, it is sufficient if the drive-area controller 244 deactivates the pixels 31 or their drive circuits.

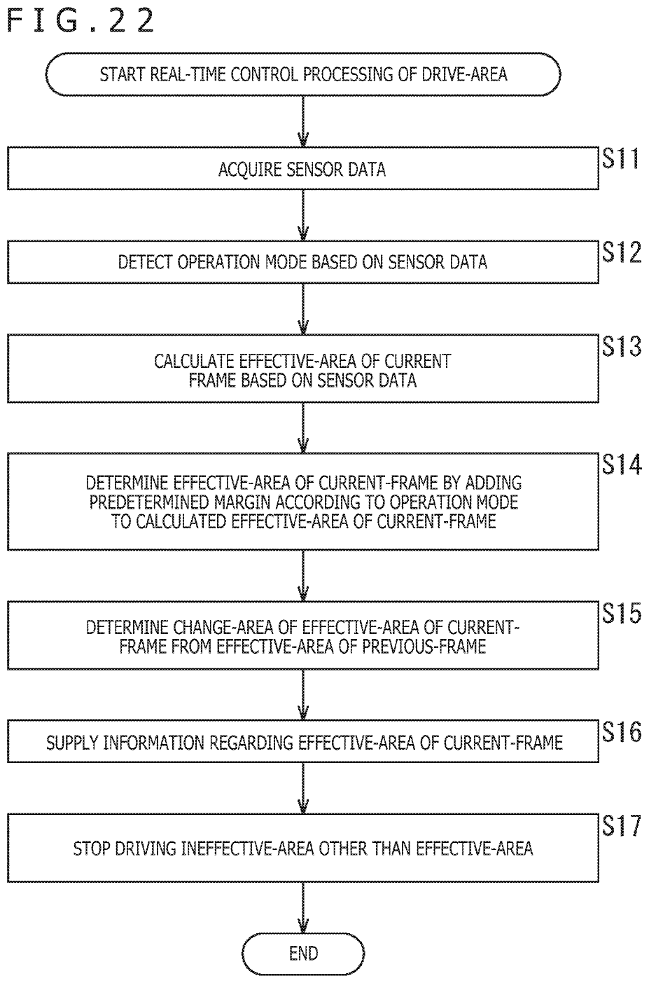

With reference to the flowchart depicted in FIG. 22, the real-time control processing of the drive area will be further described.

First, in Step S11, the system controller 15 acquires sensor data from a sensor outside the apparatus, then proceeds to Step S12. The sensor data is supplied to the mode detection section 241 and the effective-area calculation section 242.

In Step S12, the mode detection section 241 detects an operation mode on the basis of the acquired sensor data, and supplies the detected mode to the effective-area determination section 243.

In Step S13, the effective-area calculation section 242 calculates an effective area of the current frame on the basis of the acquired sensor data, and supplies the result to the effective-area determination section 243.

In Step S14, the effective-area determination section 243 adds a predetermined margin according to the operation mode determined by the mode detection section 241 to the effective area of current frame which is supplied from the effective-area calculation section 242, thereby determining an effective area of the current frame.

In Step S15, the effective-area determination section 243 acquires information, stored in the memory 245, of the effective area of a previous frame, and thereby determines a change region from the effective area of the previous frame to the effective area of the current frame.

Then, in Step S16, the effective-area determination section 243 supplies information regarding the effective area of the current frame to the drive-area controller 244.

Specifically, in the first frame, the effective-area determination section 243 supplies, to the drive-area controller 244, information indicating the whole of the effective area in the pixel array section 11, as the information regarding the effective area of the current frame. In the second and later frames, the effective-area determination section 243 supplies, to the drive-area controller 244, information indicating the change area of the effective area, as information regarding the effective area of the current frame. In addition, in Step S16, the effective-area determination section 243 causes the memory 245 to store the information indicating the effective area of the current frame as information, for the next frame, regarding the effective area of the previous frame.

In Step S17, on the basis of the information regarding the effective area of the current frame supplied from the effective-area determination section 243, the drive-area controller 244 performs control such that the drive of ineffective areas other than the effective area is halted.

The processing of Steps S11 to S17 described above is repeatedly performed at predetermined intervals, which causes the drive area to change in real time on a unit of frame basis according to the sensor data, allowing the control suited for the drive area. This configuration allows a reduction in power consumption of the solid-state imaging apparatus 1 and a reduction in the amount of output data. Moreover, the halting of a part of the drive allows a reduction of heat generation, resulting in a contribution to noise reduction. Furthermore, the power saving makes it possible to increase battery service time, simplify a heat radiating section, and also downsize the set (module) of the apparatus. The reduction of the amount of data contributes to the labor saving of an internal data bus.

### 5. Exemplary Application to Electronic Equipment

The present technology is not limited to applications to solid-state imaging apparatuses. That is, the present technology is applicable to a wide range of electronic equipment each of which adopts a solid-state imaging apparatus as its image capture section (photoelectric conversion section); such appliances include an image pickup apparatus such as a digital still camera or a video camera, a mobile terminal apparatus provided with an imaging function, a copier that uses a solid-state imaging apparatus as its image reader, and the like. The solid-state imaging apparatus may be formed in a one-chip or may be formed in a module provided with an imaging function, the module in which an imaging section and either a signal processing section or an optical system are collectively packaged.

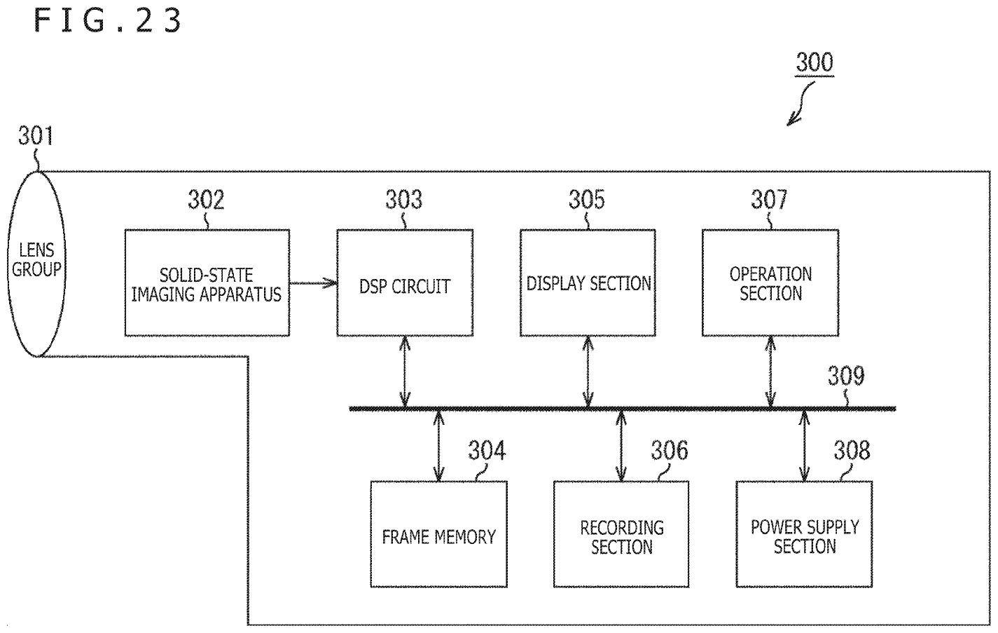

FIG. 23 is a block diagram depicting an example of a configuration of the imaging apparatus as electronic equipment to which the present technology is applied.

An imaging apparatus 300 of FIG. 23 includes an optical section 301 including a lens group and the like, a solid-state imaging apparatus (imaging device) 302 employing the configuration of the solid-state imaging apparatus 1 of FIG. 1, and a DSP (Digital Signal Processor) circuit 303 serving as a camera signal processing circuit. In addition, the imaging apparatus 300 also includes a frame memory 304, a display section 305, a recording section 306, an operation section 307, and a power supply section 308. The DSP circuit 303, the frame memory 304, the display section 305, the recording section 306, the operation section 307, and the power supply section 308 are mutually connected via a bus line 309.

The optical section 301 captures incident light (image light) from a subject and forms an image on an imaging surface of the solid-state imaging apparatus 302. The solid-state imaging apparatus 302 converts the amount of the incident light, which is caused to form the image on the imaging surface by the optical section 301, into an electric signal on a per unit of pixel basis and outputs the electric signal as a pixel signal. As the solid-state imaging apparatus 302, it is possible to use the solid-state imaging apparatus 1 of FIG. 1, that is, the solid-state imaging apparatus having the pixel array suited for photographing by using a fisheye lens (wide-angle lens).

The display section 305 includes, for example, a flat-panel display such as an LCD (Liquid Crystal Display) or an organic EL (Electro Luminescence) display, and is configured to display a moving image or a still image imaged by the solid-state imaging apparatus 302. The recording section 306 records the moving image or the still image imaged by the solid-state imaging apparatus 302 on a recording medium such as a hard disk or a semiconductor memory.

According to operations by a user, the operation section 307 issues operation instructions as to various functions of the imaging apparatus 300. The power supply section 308 appropriately supplies, to the following sections, various types of power to be used as operation power of the sections, that is, the DSP circuit 303, the frame memory 304, the display section 305, the recording section 306, and the operation section 307.

As described above, with the solid-state imaging apparatus 302, the use of the solid-state imaging apparatus 1 employing any of the above-described configurations, allows the contribution to increase in sense of resolution of the outer peripheral portions of an image photographed by using a wide-angle lens. Therefore, with the imaging apparatus 300 such as a video camera, a digital still camera, or even a camera module for use in mobile equipment such as mobile phones, it is possible to achieve an improvement in quality of photographed images.

### Exemplary Uses of Image Sensors

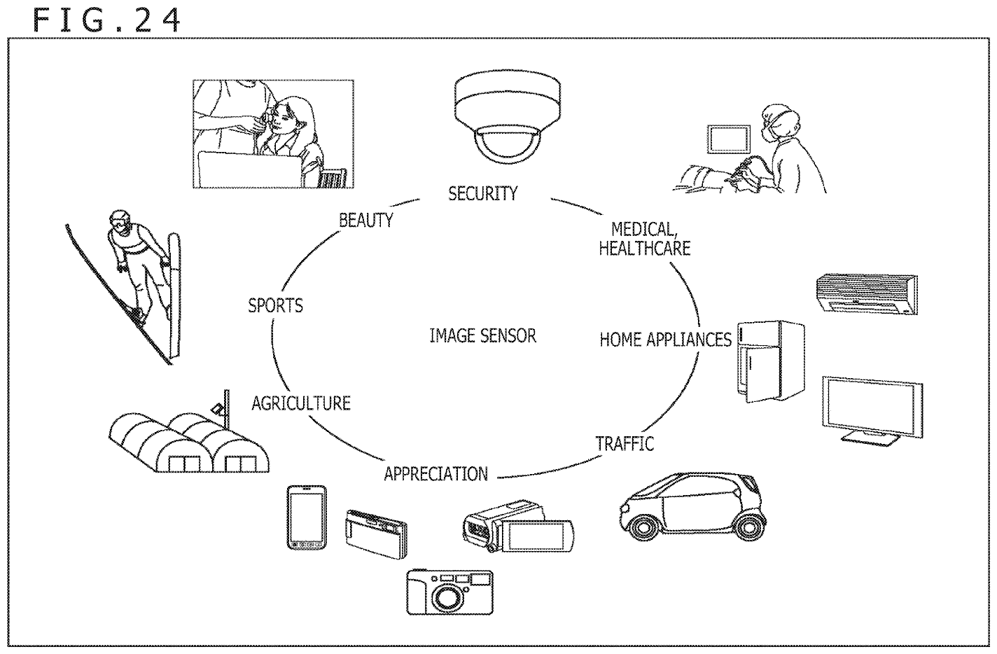

FIG. 24 is a diagram depicting examples of uses of image sensors each of which employs the solid-state imaging apparatus 1 described above.

The image sensor employing the solid-state imaging apparatus 1 described above can be used in a wide variety of applications for sensing light such as visible light, infrared light, ultraviolet light, X-rays, as follows:
Equipment for photographing images to be used for appreciation, such as digital cameras and portable equipment provided with camera function.
Equipment for use in traffic applications, for the sake of safe driving by automatic stop and of recognition of driver's condition, such as on-vehicle sensors for photographing the front, rear, surroundings, inside, etc., of a vehicle, monitoring cameras for monitoring a traveling vehicle or a road, and distance measurement sensors for measuring distances between vehicles.
Equipment for use in home appliances, such as TVs, refrigerators, and air conditioners, which are to photograph a user's gesture and to operate these appliances according to the gesture.
Equipment for use in medical and healthcare applications, such as endoscopes and equipment for photographing blood vessels by receiving infrared light.
Equipment for use in security applications, such as security cameras for crime prevention and cameras for person authentication.
Equipment for use in beauty applications, such as skin measurement equipment for photographing skin and microscopes for photographing a scalp.
Equipment for use in sports applications, such as action cameras, wearable cameras, and any other gear for sports.
Equipment for use in agriculture applications, such as cameras for monitoring the conditions of fields and crops.

### 6. Exemplary Application to Mobile Body

The technology (present technology) according to the present disclosure can be applied to various products. For example, the technology according to the present disclosure may be implemented as an apparatus to be mounted on any type of mobile body such as a motor vehicle, an electric vehicle, a hybrid electric vehicle, a motorcycle, a bicycle, a personal mobility, an airplane, a drone, a ship, a robot, or any other body.

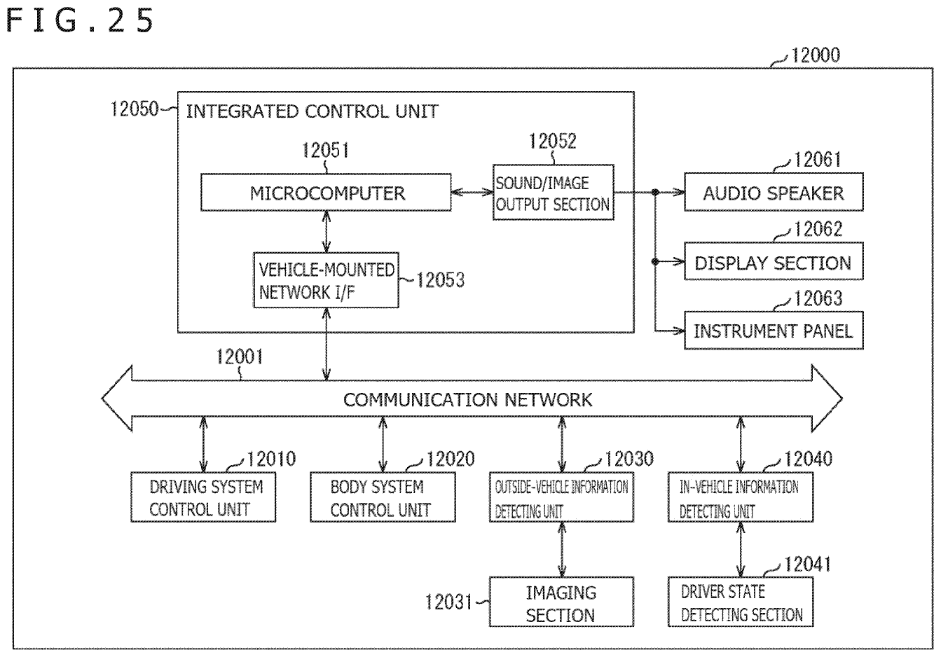

FIG. 25 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 25, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 25, an audio speaker 12061, a display section 12062, and an instrument panel 12063 are illustrated as the output device. The display section 12062 may, for example, include at least one of an on-board display and a head-up display.

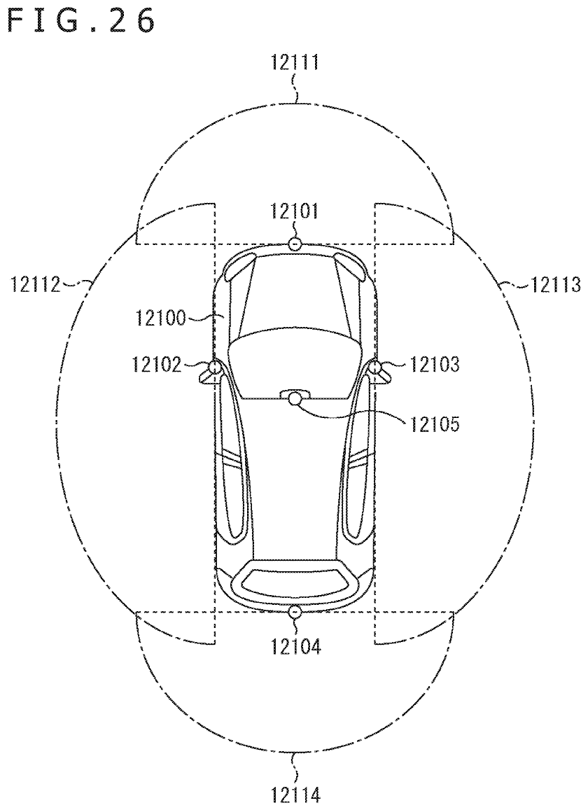

FIG. 26 is a diagram depicting an example of the installation position of the imaging section 12031.

In FIG. 26, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 26 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure is applicable to the imaging section 12031 among the configurations described above. Specifically, the solid-state imaging apparatus 1 described above can be applied to the imaging section 12031. Applying the technology according to the present disclosure to the imaging section 12031 makes it possible to obtain a photographed image of a wide visual field with improved sense of resolution at outer peripheral portions of the image. Further, use of such an obtained photographed image allows a decrease in driver's fatigue and an increase in safety of a driver and a vehicle.

The present technology is not limited to applications for solid-state imaging apparatuses each of which detects the distribution of the amount of incident light of visible light and photographs the distribution as an image. However, the present technology is applicable to a wide range of solid-state imaging apparatuses (physical quantity distribution detection apparatuses) including the followings: a solid-state imaging apparatus that photographs, as an image, the distribution of the amount of, such as, incident infrared, incident X-rays, or incident particles; a fingerprint detection sensor, in a broad sense, that detects the distribution of the amount of other physical quantity such as pressure and electrostatic capacity and photographs the distribution as an image; and any other imaging apparatus.

The embodiments of the present technology are not limited to the embodiments described above, and various modifications can be made without departing from the scope of the present technology.

In the abovementioned examples, the configuration has been described which includes the pixel array section in which a plurality of the pixels is arranged such that the pixel pitch becomes smaller at a greater distance away from the central portion toward the outer peripheral portion (circumferential portion); such an arrangement of the pixels is preferably configured as one suited for photographing by using a fisheye lens for use in a 360-degree panoramic camera. It goes without saying, however, that the present technology is applicable not only to fisheye lenses but also to other wide-angle lenses.

For example, all or a part of a plurality of the exemplary configurations described above may be appropriately combined into another configuration to be adopted.

Note that the effects described in the present specification are illustrative only, there is no limitation to the effects, and effects other than the effects described in the present specification may be present.

It is to be noted that the present technology may provide the following configurations.

(1)

A solid-state imaging apparatus including:

a pixel array section including a plurality of pixels arranged with a pixel pitch, the pixel array section having a central portion and an outer peripheral portion, the pixel pitch being smaller at a greater distance away from the central portion toward the outer peripheral portion.

(2)

The solid-state imaging apparatus according to (1), in which the pixel array section has a pixel arrangement including a concentric arrangement.

(3)

The solid-state imaging apparatus according to (1) or (2), in which each of the pixels has one of a rectangular shape, a concentric circular shape, and a concentric polygonal shape.

(4)

The solid-state imaging apparatus according to any one of (1) to (3), further including:

a pixel drive line configured to transmit a drive signal for driving the pixels; and

an output signal line configured to output, to an outside of the pixels, a pixel signal generated by the pixels,

in which the pixel drive line and the output signal line are each disposed to extend linearly in one of a horizontal direction and a vertical direction.

(5)

The solid-state imaging apparatus according to any one of (1) to (3), further including:

a pixel drive line configured to transmit a drive signal for driving the pixels; and

an output signal line configured to output, to an outside of the pixels, a pixel signal generated by the pixels,

in which the pixel drive line is disposed on a per unit-of-pixel basis, the unit-of-pixel including pixels that include the plurality of pixels and are arranged on a circumference of a predetermined radius, and

the output signal line is disposed along a direction of the radius of a concentric circle having the circumference on which the pixels are arranged.

(6)

The solid-state imaging apparatus according to any one of (1) to (5), further including:

an AD conversion section configured to perform AD conversion to a pixel signal output by the pixels,

in which the pixel array section has a pixel arrangement including a concentric arrangement, and

the AD conversion section is disposed on a circumference outside the pixel array section formed in a circular shape.

(7)

The solid-state imaging apparatus according to (6),

in which a pixel drive section configured to drive the pixels is disposed outside the AD conversion section disposed on the circumference of the pixel array section.

(8)

The solid-state imaging apparatus according to (6) or (7), further including:

an OPB region where an OPB pixel is disposed on an outermost circumference of the pixel array section, the pixel array section formed in the circular shape.

(9)

The solid-state imaging apparatus according to any one of (1) to (8),

in which each of the pixels includes an on-chip lens, and the on-chip lens has a curvature, the curvature being different between the pixel located on a central portion side of the pixel array section and the pixel located on an outer peripheral portion side of the pixel array section.

(10)

The solid-state imaging apparatus according to any one of (1) to (8),

in which each of the pixels includes an on-chip lens, and

the on-chip lens has a curvature, the curvature being identical for all the pixels.

(11)

The solid-state imaging apparatus according to any one of (1) to (10), further including:

an AD conversion section disposed for each of the pixels and configured to perform AD conversion to a pixel signal output by the pixel.

(12)

The solid-state imaging apparatus according to any one of (1) to (11),

in which the plurality of pixels in the pixel array section is two-dimensionally arranged in a matrix.

(13)

The solid-state imaging apparatus according to (12),

in which each of the pixels is formed to have a size such that the size is large at the central portion of the pixel array section and is smaller at a greater distance away from the central portion toward the outer peripheral portion of the pixel array section.

(14)

The solid-state imaging apparatus according to (12) or (13), further including:

a pixel drive line configured to transmit a drive signal for driving the pixels; and

an output signal line configured to output, to an outside of the pixels, a pixel signal generated by the pixels, in which each of the pixel drive line and the output signal line is disposed such that a space between neighboring line is smaller at a greater distance away from the central portion of the pixel array section toward the outer peripheral portion of the pixel array section.

(15)

The solid-state imaging apparatus according to any one of (12) to (14),

in which the pixel array section includes
a projection region onto which an image of a subject is projected, the projection region including a circular region, and
a non-projection region onto which no image of the subject is projected, pixels located in the non-projection region failing to be subjected to pixel drive for light-receiving and reading.
   (16)

The solid-state imaging apparatus according to any one of (12) to (15),

in which the pixel array section includes
a projection region onto which an image of a subject is projected, the projection region including a circular region, and
a non-projection region onto which no image of the subject is projected, the non-projection region including an OPB region in which an OPB pixel is arranged.
   (17)

The solid-state imaging apparatus according to any one of (12) to (16),

in which the pixel array section includes sub-pixels arranged two-dimensionally in a matrix, the sub-pixels having an equal size and producing pixel signals, and

the pixel signals of the sub-pixels are combined and output on a per unit of a set of sub-pixels basis, and the pixel array section is configured to have a different pixel pitch by changing the unit of the set of the sub-pixels according to a location in the pixel array section such that the pixel pitch is smaller at a greater distance away from the central portion toward the outer peripheral portion.

(18)

A solid-state imaging apparatus including:

a pixel array section including a plurality of pixels; and

a controller configured to
determine an effective area for the plurality of pixels in the pixel array section such that drive of pixels is performed, and
perform control such that drive of pixels, among the plurality of pixels, located outside the effective area is halted.
   (19)

The solid-state imaging apparatus according to (18),

in which, on the basis of received sensor data, the controller determines the effective area on a per frame basis and performs the control such that the drive of the pixels located outside the effective area is halted.

(20)

Electronic equipment including:

a solid-state imaging apparatus including a pixel array section including a plurality of pixels arranged with a pixel pitch, the pixel array section having a central portion and an outer peripheral portion, the pixel pitch being smaller at a greater distance away from the central portion toward the outer peripheral portion.

### REFERENCE SIGNS LIST

1: Solid-state imaging apparatus
11: Pixel array section
12: V scanner
13: AD conversion section
14: H scanner
15: System controller
21: Pixel drive line
22: Output signal line
31: Pixel
PD: Photodiode
41: ADC
61: AD conversion section
62: r-scanner
63: OPB region
74: On-chip lens
211: Effective area
241: Mode detection section
242: Effective-area calculation section
243: Effective-area determination section
244: Drive-area controller
245: Memory
300: Imaging apparatus
302: Solid-state imaging apparatus

1. A solid-state imaging apparatus comprising:
a pixel array section including a plurality of pixels arranged with a pixel pitch, the pixel array section having a central portion and an outer peripheral portion, the pixel pitch being smaller at a greater distance away from the central portion toward the outer peripheral portion.

2. The solid-state imaging apparatus according to claim 1,
wherein the pixel array section has a pixel arrangement including a concentric arrangement.

3. The solid-state imaging apparatus according to claim 1,
wherein each of the pixels has one of a rectangular shape, a concentric circular shape, and a concentric polygonal shape.

4. The solid-state imaging apparatus according to claim 1, further comprising:
a pixel drive line configured to transmit a drive signal for driving the pixels; and
an output signal line configured to output, to an outside of the pixels, a pixel signal generated by the pixels,
wherein the pixel drive line and the output signal line are each disposed to extend linearly in one of a horizontal direction and a vertical direction.

5. The solid-state imaging apparatus according to claim 1, further comprising:
a pixel drive line configured to transmit a drive signal for driving the pixels; and
an output signal line configured to output, to an outside of the pixels, a pixel signal generated by the pixels,
wherein the pixel drive line is disposed on a per unit-of-pixel basis, the unit-of-pixel including pixels that include the plurality of pixels and are arranged on a circumference of a predetermined radius, and
the output signal line is disposed along a direction of the radius of a concentric circle having the circumference on which the pixels are arranged.

6. The solid-state imaging apparatus according to claim 1, further comprising:
an AD conversion section configured to perform AD conversion to a pixel signal output by the pixels,
wherein the pixel array section has a pixel arrangement including a concentric arrangement, and
the AD conversion section is disposed on a circumference outside the pixel array section formed in a circular shape.

7. The solid-state imaging apparatus according to claim 6,
wherein a pixel drive section configured to drive the pixels is disposed outside the AD conversion section disposed on the circumference of the pixel array section.

8. The solid-state imaging apparatus according to claim 6, further comprising:
an OPB region where an OPB pixel is disposed on an outermost circumference of the pixel array section, the pixel array section formed in the circular shape.

9. The solid-state imaging apparatus according to claim 1,
wherein each of the pixels includes an on-chip lens, and
the on-chip lens has a curvature, the curvature being different between the pixel located on a central portion side of the pixel array section and the pixel located on an outer peripheral portion side of the pixel array section.

10. The solid-state imaging apparatus according to claim 1,
wherein each of the pixels includes an on-chip lens, and
the on-chip lens has a curvature, the curvature being identical for all the pixels.

11. The solid-state imaging apparatus according to claim 1, further comprising:
an AD conversion section disposed for each of the pixels and configured to perform AD conversion to a pixel signal output by the pixel.

12. The solid-state imaging apparatus according to claim 1,
wherein the plurality of pixels in the pixel array section is two-dimensionally arranged in a matrix.

13. The solid-state imaging apparatus according to claim 12,
wherein each of the pixels is formed to have a size such that the size is large at the central portion of the pixel array section and is smaller at a greater distance away from the central portion toward the outer peripheral portion of the pixel array section.

14. The solid-state imaging apparatus according to claim 12, further comprising:
a pixel drive line configured to transmit a drive signal for driving the pixels; and
an output signal line configured to output, to an outside of the pixels, a pixel signal generated by the pixels,
wherein each of the pixel drive line and the output signal line is disposed such that a space between neighboring line is smaller at a greater distance away from the central portion of the pixel array section toward the outer peripheral portion of the pixel array section.

15. The solid-state imaging apparatus according to claim 12,
wherein the pixel array section includes
a projection region onto which an image of a subject is projected, the projection region including a circular region, and
a non-projection region onto which no image of the subject is projected, pixels located in the non-projection region failing to be subjected to pixel drive for light-receiving and reading.

16. The solid-state imaging apparatus according to claim 12,
wherein the pixel array section includes
a projection region onto which an image of a subject is projected, the projection region including a circular region, and
a non-projection region onto which no image of the subject is projected, the non-projection region including an OPB region in which an OPB pixel is arranged.

17. The solid-state imaging apparatus according to claim 12,
wherein the pixel array section includes sub-pixels arranged two-dimensionally in a matrix, the sub-pixels having an equal size and producing pixel signals, and
the pixel signals of the sub-pixels are combined and output on a per unit of a set of sub-pixels basis, and the pixel array section is configured to have a different pixel pitch by changing the unit of the set of the sub-pixels according to a location in the pixel array section such that the pixel pitch is smaller at a greater distance away from the central portion toward the outer peripheral portion.

18. A solid-state imaging apparatus comprising:
a pixel array section including a plurality of pixels; and
a controller configured to
determine an effective area for the plurality of pixels in the pixel array section such that drive of pixels is performed, and
perform control such that drive of pixels, among the plurality of pixels, located outside the effective area is halted.

19. The solid-state imaging apparatus according to claim 18,
wherein, on a basis of received sensor data, the controller determines the effective area on a per frame basis and performs the control such that the drive of the pixels located outside the effective area is halted.

20. Electronic equipment comprising:
a solid-state imaging apparatus including a pixel array section including a plurality of pixels arranged with a pixel pitch, the pixel array section having a central portion and an outer peripheral portion, the pixel pitch being smaller at a greater distance away from the central portion toward the outer peripheral portion.
